(19) United States
(12) Patent Application Publication
(10) Pub. No.: US 2026/0101644 A1
(43) Pub. Date: Apr. 9, 2026

(54) LIGHT EMITTING DEVICE INCLUDING PLANARIZING FILM FORMED OF CURED PRODUCT OF CURABLE COMPOSITION

(71) Applicant: CANON KABUSHIKI KAISHA, Tokyo (JP)

(72) Inventors: KOUJI OZAKI, Kanagawa (JP); AKINORI MAKAINO, Kanagawa (JP)

(21) Appl. No.: 19/344,012

(22) Filed: Sep. 29, 2025

(30) Foreign Application Priority Data
Oct. 4, 2024 (JP) 2024-175263

(51) Int. Cl. H10K 59/122; H10K 59/12; H10K 59/80

(52) U.S. Cl. CPC H10K 59/122; H10K 59/1201; H10K 59/873

(57) ABSTRACT

A light emitting device includes a plurality of lower electrodes arranged on a substrate, and a bank insulating film configured to cover a peripheral portion of an upper surface of each of the plurality of lower electrodes and expose a central portion of the upper surface. The device also includes a planarizing film arranged on at least the plurality of lower electrodes and the bank insulating film, and formed of a cured product of a curable composition.

### BACKGROUND

### Field of the Technology

There is a light emitting device that includes a plurality of lower electrodes arranged on a substrate, and an insulating film (bank) covering the peripheral portion of the upper surface of each of the plurality of lower electrodes and the substrate between the plurality of lower electrodes. In this light emitting device, the unevenness generated due to the presence of the insulating film can extend to an upper electrode and even to a layer above it. Since the unevenness existing above the upper electrode refracts light emitted from a light emitting layer, this can deteriorate the light extraction efficiency and the color purity.

The present disclosure relates to a light emitting device, a manufacturing method thereof, and a device including the light emitting device.

### Description of the Related Art

Japanese Patent Laid-Open No. 2019-061927 describes an arrangement in which a common electrode is arranged above an insulating layer (bank), which divides a plurality of pixel electrodes, via an organic electroluminescence layer, and a sealing layer, a filling layer, and the second substrate are sequentially arranged on the common electrode. Since the upper surface of the filling layer is flatter than the lower surface of the filling layer, it can also be said that the filling layer has an aspect as a planarizing layer. Note that patent literature 1 does not describe a material for the filling layer.

A planarizing layer can be implemented by, for example, a thick film which is formed on an uneven underlying surface by a CVD method or the like. However, even if the thick film is formed, some unevenness depending on the unevenness of the underlying surface or the film formation method can be formed in the upper surface of the thick film. In addition, formation of the thick film can lead to an increase in manufacturing cost and a deterioration in optical characteristic (for example, a deterioration in color purity or a deterioration in luminance).

### SUMMARY

The present disclosure provides a technique advantageous in reducing the manufacturing cost and/or improving the optical characteristic.

The present disclosure includes a light emitting device that comprises a plurality of lower electrodes arranged on a substrate, and a bank insulating film configured to cover a peripheral portion of an upper surface of each of the plurality of lower electrodes and expose a central portion of the upper surface, the device comprising a planarizing film arranged on at least the plurality of lower electrodes and the bank insulating film, and formed of a cured product of a curable composition.

Features of the present disclosure will become apparent from the following description of embodiments with reference to the attached drawings. The following description of embodiments is described by way of example.

### BRIEF DESCRIPTION OF THE DRAWINGS

FIG. 1 is a view schematically showing the arrangement of a light emitting device according to an embodiment;

FIG. 2 is an enlarged view of a portion of FIG. 1;

FIG. 3 is a view schematically showing the arrangement of a light emitting device according to another embodiment;

FIG. 4 is a view schematically showing an example of the arrangement of a planarization apparatus that can be used to form a planarizing film;

FIG. 5 is a view schematically showing a step of processing for forming the planarizing film of the light emitting device shown in FIG. 1;

FIG. 6 is a view schematically showing a step of processing for forming the planarizing film of the light emitting device shown in FIG. 1;

FIG. 7 is a view schematically showing a step of processing for forming the planarizing film of the light emitting device shown in FIG. 1;

FIG. 8 is a view schematically showing a step of processing for forming the planarizing film of the light emitting device shown in FIG. 1;

FIG. 9 is a view schematically showing a step of processing for forming the planarizing film of the light emitting device shown in FIG. 3;

FIG. 10 is a view schematically showing a step of processing for forming the planarizing film of the light emitting device shown in FIG. 3;

FIG. 11 is a view schematically showing a step of processing for forming the planarizing film of the light emitting device shown in FIG. 3;

FIG. 12 is a view schematically showing a step of processing for forming the planarizing film of the light emitting device shown in FIG. 3;

FIG. 13 is a view schematically showing the arrangement of the first modification of the light emitting device shown in FIG. 1;

FIG. 14 is a view schematically showing the arrangement of the second modification of the light emitting device shown in FIG. 1;

FIG. 15 is a view schematically showing the arrangement of the third modification of the light emitting device shown in FIG. 1;

FIGS. 16A and 16B are views exemplifying an application example of the light emitting device;

FIGS. 17A to 17C are views exemplifying an application example of the light emitting device;

FIG. 18 is a view exemplifying an application example of the light emitting device;

FIG. 19 is a view exemplifying an application example of the light emitting device;

FIG. 20 is a view exemplifying an application example of the light emitting device;

FIGS. 21A and 21B are views each exemplifying an application example of the light emitting device;

FIG. 22 is a view exemplifying an application example of the light emitting device;

FIG. 23 is a view exemplifying an application example of the light emitting device; and

FIGS. 24A and 24B are views each exemplifying an application example of the light emitting device.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

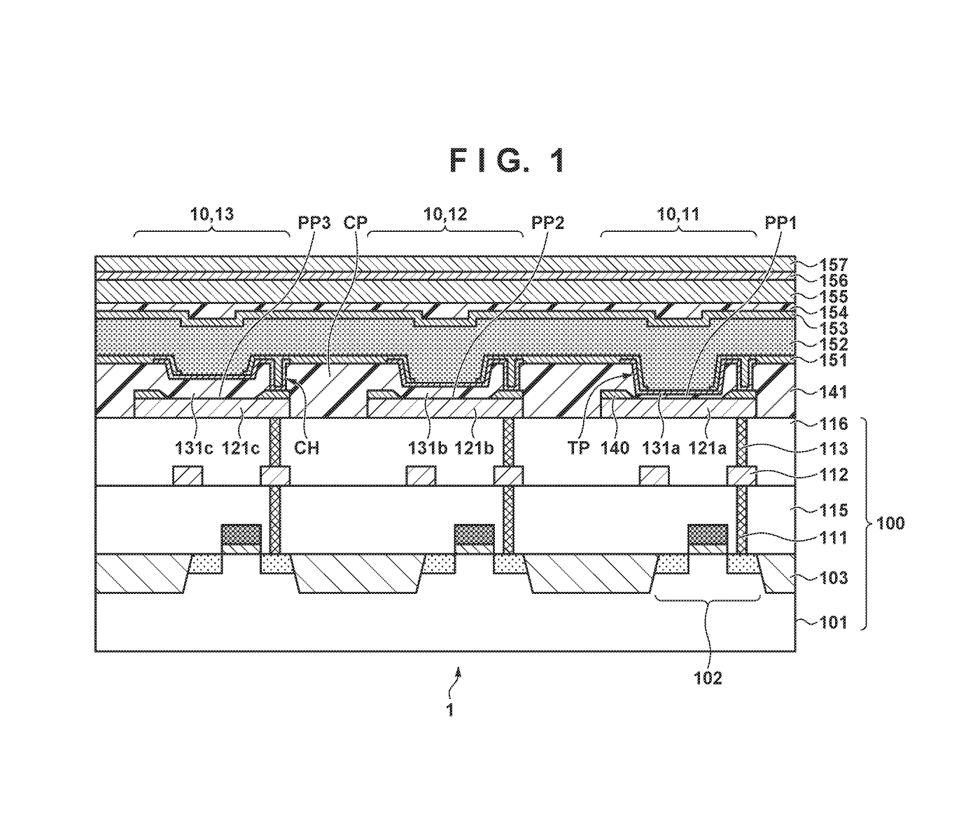

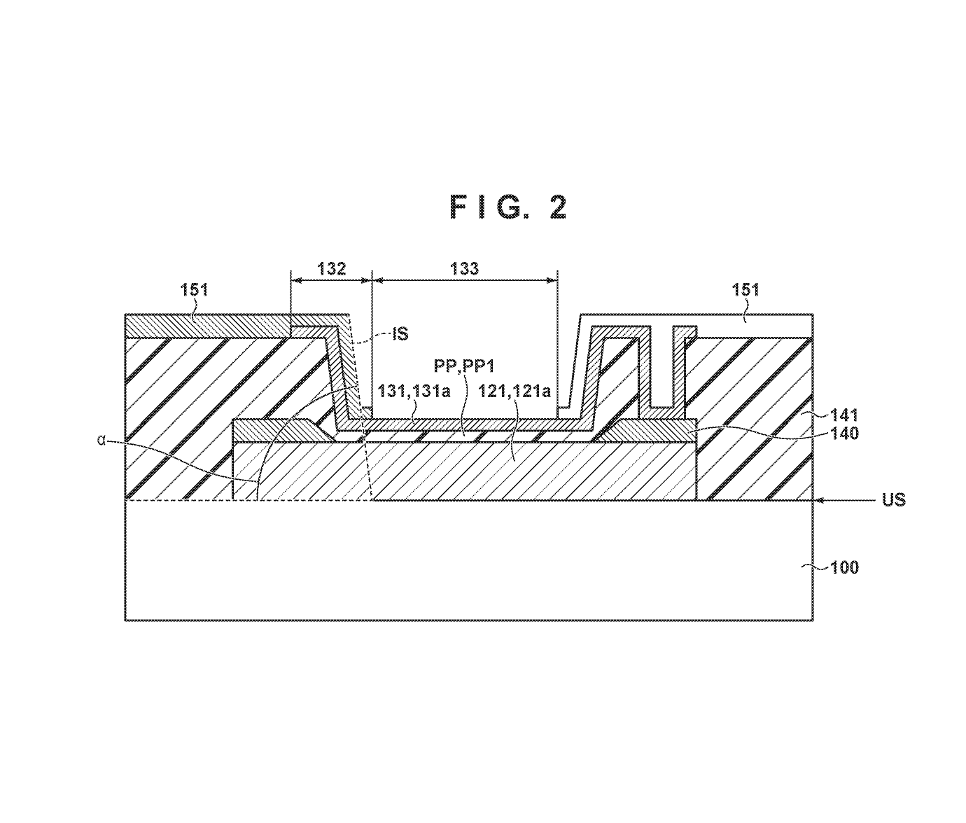

FIG. 1 schematically shows the arrangement of a light emitting device 1 according to an embodiment. FIG. 2 schematically shows an enlarged view of a portion of FIG. 1. The light emitting device 1 can be formed as a device called an organic light emitting device, an organic EL device, or an OLED. The light emitting device 1 can be formed as a display device. The light emitting device 1 includes a plurality of pixels, and each pixel can include a plurality of sub-pixels 10. In one aspect, the plurality of sub-pixels 10 can include a first sub-pixel 11 and a second sub-pixel 12. In another aspect, the plurality of sub-pixels 10 can include the first sub-pixel 11, the second sub-pixel 12, and a third sub-pixel 13. The first sub-pixel 11, the second sub-pixel 12, and the third sub-pixel 13 are sub-pixels that generate light components of colors (wavelength bands) different from each other. Each pixel may include more sub-pixels. In an example, the first sub-pixel 11 is a sub-pixel that generates blue light, the second sub-pixel 12 is a sub-pixel that generates green light, and the third sub-pixel 13 is a sub-pixel that generates red light. Note that FIG. 1 shows only one first sub-pixel 11, one second sub-pixel 12, and one third sub-pixel 13, but the light emitting device 1 is formed to include more sub-pixels 10 in accordance with an application purpose.

The first sub-pixel 11 can include a first reflecting member 121a and a first lower electrode 131a. The second sub-pixel 12 can include a second reflecting member 121b and a second lower electrode 131b. The third sub-pixel 13 can include a third reflecting member 121c and a third lower electrode 131c. Here, when describing the first reflecting member 121a, the second reflecting member 121b, and the third reflecting member 121c without distinguishing them from each other, they are referred to as reflecting members 121. Similarly, when describing the first lower electrode 131a, the second lower electrode 131b, and the third lower electrode 131c without distinguishing them from each other, they are referred to as lower electrodes 131. For example, the reflecting member 121 can be made of Ti, Al, or AlCu, or have a stacked structure of Ti/AlCu.

The sub-pixel 10 includes the lower electrode 131 and an upper electrode 153. An organic compound film 152 including a light emitting layer is arranged between the lower electrode 131 and the upper electrode 153. In the example shown in FIG. 1, the lower electrode 131 of each of the plurality of sub-pixels 10 is an individual electrodes provided for each sub-pixel 10, and the upper electrodes 153 of the plurality of sub-pixels 10 form a common electrode provided commonly for the plurality of sub-pixels 10. However, the upper electrodes 153 of the plurality of sub-pixels 10 may be provided individually for the plurality of sub-pixels 10. In such a case, the individual upper electrode 153 can be electrically connected to the reflecting member 121 or a driving element arranged below it, and the lower electrodes 131 of the plurality of sub-pixels 10 can be provided commonly for the plurality of sub-pixels 10.

The reflecting members 121 of the plurality of sub-pixels 10 can be arranged on a substrate 100. The lower electrodes 131 of the plurality of sub-pixels 10 can be driven by driving elements such as transistors 102 arranged in the substrate 100. The substrate 100 can include, for example, a semiconductor substrate 101 where a plurality of transistors 102 are arranged, interlayer insulating films 115 and 116, vias 111 and 113, and a wiring layer (wiring pattern) 112.

In each sub-pixel 10, as exemplified in FIG. 1, the reflecting member 121 and the lower electrode 131 arranged above it can be electrically connected via, for example, a barrier metal 140. Alternatively, the reflecting member 121 may be electrically insulated from the lower electrode 131, and a fixed potential may be applied to the reflecting member 121. The barrier metal 140 can be formed of, for example, Ti, TiN, or a stacked film of Ti/TiN.

An insulating film 141 is arranged between the reflecting member 121 and the lower electrode 131. The insulating film 141 is arranged between the reflecting member 121 and the lower electrode 131, and can also be arranged between the reflecting members 121 adjacent to each other. In each sub-pixel 10, the insulating film 141 is arranged so as to define the spacing (optical distance) between the reflecting member 121 and the lower electrode 131, so that it can function as an optical adjustment film for allowing radiation of light of a specific wavelength band from the sub-pixel 10. More specifically, in the first sub-pixel 11 that can be configured as a blue sub-pixel, the spacing (optical distance) between the first reflecting member 121a and the first lower electrode 131a is decided so as to allow radiation of blue light from the first sub-pixel 11. In the second sub-pixel 12 that can be configured as a green sub-pixel, the spacing (optical distance) between the second reflecting member 121b and the second lower electrode 131b is decided so as to allow radiation of green light from the second sub-pixel 12. In the third sub-pixel 13 that can be configured as a red sub-pixel, the spacing (optical distance) between the third reflecting member 121c and the third lower electrode 131c is decided so as to allow radiation of red light from the third sub-pixel 13. Each optical distance may be adjusted by the thickness of the lower electrode. In this case, the insulating film 141 may not be provided between the reflecting member and the lower electrode.

The insulating film 141 can include a first portion PP1 arranged between the first reflecting member 121a and the first lower electrode 131a, and a second portion PP2 arranged between the second reflecting member 121b and the second lower electrode 131b. The thickness of the first portion PP1 and the thickness of the second portion PP2 can be different from each other. In another viewpoint, the spacing between the first reflecting member 121a and the first lower electrode 131a and the spacing between the second reflecting member 121b and the second lower electrode 131b can be different from each other. The insulating film 141 can also include a connecting portion CP connecting the first portion PP1 and the second portion PP2. The distance between the upper surface of the connecting portion CP and the upper surface of the substrate 100 is larger than the distance between the upper surface of the first portion PP1 and the upper surface of the substrate 100 and the distance between the upper surface of the second portion PP2 and the upper surface of the substrate 100.

The insulating film 141 can further include a third portion PP3 arranged between the third reflecting member 121c and the third lower electrode 131c. The thickness of the first portion PP1, the thickness of the second portion PP2, and the thickness of the third portion PP3 can be different from each other. In another viewpoint, the spacing between the first reflecting member 121a and the first lower electrode 131a, the spacing between the second reflecting member 121b and the second lower electrode 131b, and the spacing between the third reflecting member 121c and the third lower electrode 131c can be different from each other. The connecting portion CP can connect the first portion PP1, the second portion PP2, and the third portion PP3. The distance between the upper surface of the connecting portion CP and the upper surface of the substrate 100 is larger than the distance between the upper surface of the first portion PP1 and the upper surface of the substrate 100, the distance between the upper surface of the second portion PP2 and the upper surface of the substrate 100, and the distance between the upper surface of the third portion PP3 and the upper surface of the substrate 100. When describing the first portion PP1, the second portion PP2, and the third portion PP3 without distinguishing them from each other, they are referred to as optical adjustment films PP. The reflecting members 121 and the optical adjustment films PP are optional components.

As schematically shown in FIG. 1, the first lower electrode 131a can have a tapered shape where the width of the first lower electrode 131a in a direction parallel to the upper surface of the substrate 100 increases as the distance from the first reflecting member 121a increases. The second lower electrode 131b can have a tapered shape where the width of the second lower electrode 131b in a direction parallel to the upper surface of the substrate 100 increases as the distance from the second reflecting member 121b increases. The third lower electrode 131c can have a tapered shape where the width of the third lower electrode 131c in a direction parallel to the upper surface of the substrate 100 increases as the distance from the third reflecting member 121c increases. The upper surface of the insulating film 141 can have tapered surfaces TP between the upper surface of the connecting portion CP and the upper surface of the first portion PP1, between the upper surface of the connecting portion CP and the upper surface of the second portion PP2, and between the upper surface of the connecting portion CP and the upper surface of the third portion PP3.

As shown in FIG. 2, a bank insulating film 151 can be arranged to cover a peripheral portion 132 of the upper surface of each of the plurality of lower electrodes 131 and expose a central portion 133 of the upper surface. Here, the central portion 133 is a portion inside the peripheral portion 132. The bank insulating film 151 can be arranged to cover the substrate 100 (in another viewpoint, the substrate 100 and the insulating film 141) between the plurality of lower electrodes 131. The surface (the surface that contacts or faces the organic compound film 152) of the bank insulating film 151 can include an inclined surface IS inclined toward the central portion 133 of the lower electrode 131. In a section (FIG. 2) perpendicular to an upper surface US of the substrate 100, an angle α formed by the inclined surface IS (an extended line thereof) and the upper surface US of the substrate 100 may be, for example, 30° (inclusive) to 90° (inclusive), preferably 50° (inclusive) to 90° (inclusive), and more preferably 80° (inclusive) to 90° (inclusive). This arrangement is advantageous for arranging the sub-pixels 10 at a high density, but it can degrade the flatness of the upper surface of the organic compound film 152. The bank insulating film 151 can be a film formed of an inorganic substance, for example, silicon oxide, silicon oxynitride, or silicon nitride.

The organic compound film 152 arranged between the lower electrodes 131 and the upper electrode 153 can be arranged to cover the plurality of lower electrodes 131 and the bank insulating film 151. The organic compound film 152 includes at least a light emitting layer. In an example, the organic compound film 152 can include a hole injection layer, a hole transport layer, an electron blocking layer, a light emitting layer, a hole blocking layer, an electron transport layer, an electron injection layer, and the like.

The light emitting device 1 can include a planarizing film 154 arranged on at least the plurality of lower electrodes 131 and the bank insulating film 151. The planarizing film 154 can be formed of a cured product of a curable composition. The planarizing film 154 can have a maximum film thickness of, for example, 0.1 μm (inclusive) to 2 μm (inclusive). The planarizing film 154 may have a stacked structure formed from a plurality of layers, and each layer may be formed of a cured product of a curable composition.

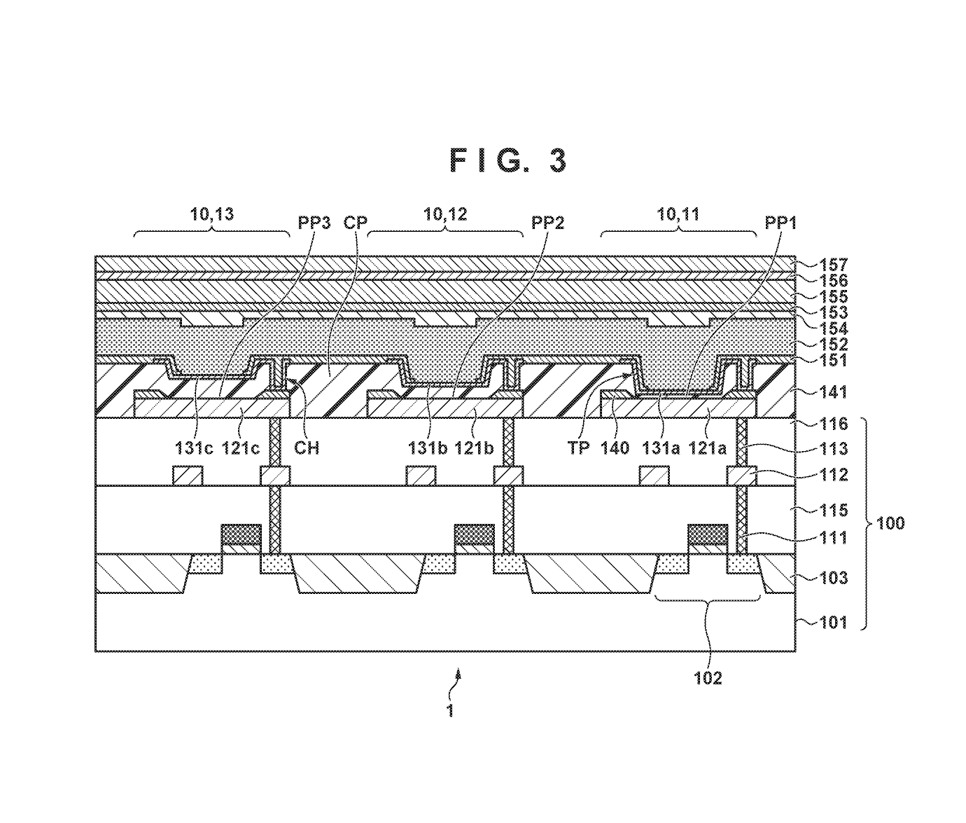

For example, the planarizing film 154 can be arranged on the upper electrode 153 as exemplarily shown in FIG. 1. Alternatively, the planarizing film 154 may be arranged between the organic compound film 152 and the upper electrode 153 as exemplified in FIG. 3. In a case where the planarizing film 154 is arranged between the organic compound film 152 and the upper electrode 153, the planarizing film 154 is formed of an electrically conductive material. An electrically conductive curable composition can be, for example, one material selected from the group consisting of polyacetylene, poly(p-phenylene vinylene), polypyrrole, polythiophene, polyaniline, and polyphenylene sulfide.

One or a plurality of sealing films can be arranged on the upper electrode 153 and the planarizing film 154. In an example, a first sealing film 155, a second sealing film 156, and a third sealing film 157 can be arranged on the upper electrode 153 and the planarizing film 154. The first sealing film 155 is, for example, a silicon nitride film. The second sealing film 156 is, for example, an aluminum oxide film. The third sealing film 157 is, for example, a silicon nitride film. On these sealing films, a color filter array and/or a microlens array may be arranged.

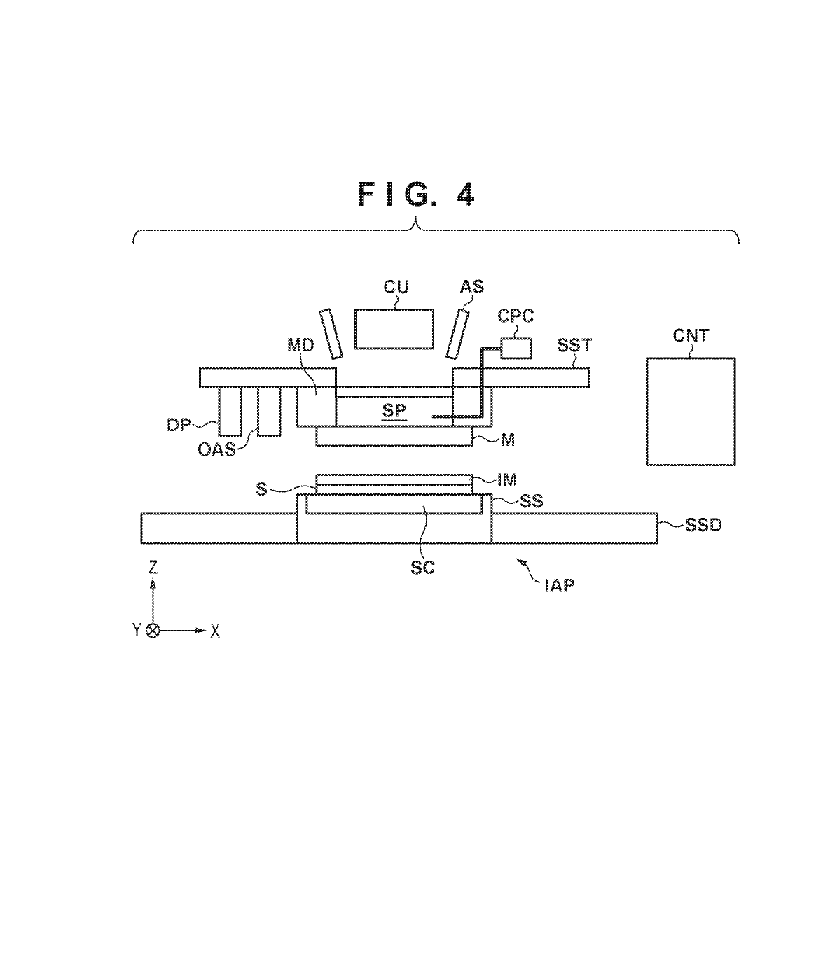

FIG. 4 schematically shows an example of the arrangement of a planarization apparatus IAP that can be used to form the planarizing film 154. The planarization apparatus IAP is an apparatus that forms the planarizing film 154 by molding a curable composition IM on a substrate S using a superstrate as a mold M. The superstrate includes a flat surface larger than the region of the surface of the substrate S where a planarizing film is to be formed. As the curable composition IM, a composition (to be also referred to as a resin in an uncured state) to be cured by receiving curing energy is used. As the curing energy, an electromagnetic wave, heat, or the like is used. The electromagnetic wave is light selected from the wavelength range of 10 nm (inclusive) to 1 mm (inclusive), for example, infrared light, a visible light beam, ultraviolet light, or the like. The curable composition IM may be understood as a composition cured by light irradiation or a composition cured by heating. Among these, a photo-curable composition cured by light contains at least a polymerizable compound and a photopolymerization initiator, and may contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component. The curable composition IM can be applied, onto the substrate, in a film shape by a spin coater or a slit coater. The curable composition IM may be applied, onto the substrate, in a droplet shape or in an island or film shape formed by connecting a plurality of droplets using a liquid injection head. The viscosity (the viscosity at 25°C) of the curable composition IM is, for example, 1 mPa∙s (inclusive) to 100 mPa∙s (inclusive).

The planarization apparatus IAP can include a substrate stage SS including a substrate chuck SC that holds the substrate S, and a substrate driving mechanism SD that drives the substrate stage SS. The planarization apparatus IAP can also include a mold driving mechanism MD that holds and drives the mold M. The substrate driving mechanism SD and the mold driving mechanism MD constitute a relative driving mechanism that drives at least one of the substrate S and the mold M to adjust the relative position between the substrate S and the mold M. Adjustment of the relative position by the relative driving mechanism includes driving for bringing the mold M into contact with the curable composition IM on the substrate S and driving for separating the mold M from the cured product (the pattern of the cured product) of the curable composition IM. Adjustment of the relative position by the relative driving mechanism also includes alignment between the substrate S and the mold M. The substrate driving mechanism SD can be configured to drive the substrate S with respect to a plurality of axes (for example, three axes including the X-axis, Y-axis, and θZ-axis, and preferably six axes including the X-axis, Y-axis, Z-axis, θX-axis, θY-axis, and θZ-axis). The mold driving mechanism MD can be configured to drive the mold M with respect to a plurality of axes (for example, three axes including the Z-axis, θX-axis, and θY-axis, and preferably six axes including the X-axis, Y-axis, Z-axis, θX-axis, θY-axis, and θZ-axis). The planarization apparatus IAP can include a pressure controller CPC that controls the three-dimensional shape of a pattern region PR of the mold M by adjusting the pressure in a sealed space SP formed on the back surface of the mold M. It is possible to deform the pattern region PR of the mold M into a downward convex shape or planarize it by adjusting the pressure in the sealed space SP by the pressure controller CPC.

The planarization apparatus IAP can include one or a plurality of alignment scopes AS for measuring the alignment error between the substrate S and the mold M. The planarization apparatus IAP can include a curing unit CU that forms a cured pattern by curing the curable composition IM by applying curing energy to the curable composition IM via the mold M. The planarization apparatus IAP can include a dispenser DP that applies or arranges the curable composition IM onto the substrate S. The planarization apparatus IAP can include an off-axis scope OAS for detecting the position of the alignment mark of the substrate S. The planarization apparatus IAP can include a control unit CNT that controls the respective components of the planarization apparatus IAP. The control unit CNT is an information processing apparatus that can be formed from, for example, a PLD (the abbreviation of Programmable Logic Device) such as an FPGA (the abbreviation of Field Programmable Gate Array), an ASIC (the abbreviation of Application Specific Integrated Circuit), a computer incorporating a program, or a combination of some or all of these.

A manufacturing method of the light emitting device 1 schematically shown in FIG. 1 will be exemplarily described below. First, with reference to FIG. 1, a manufacturing method of the substrate 100 will be described. First of all, elements such as the plurality of transistors 102 electrically isolated from each other by element isolations 103 can be formed in the semiconductor substrate 101. Then, the interlayer insulating films 115 and 116, the vias 111 and 113, the wiring layer 112, and the like are formed.

Then, the plurality of reflecting members 121 including the first reflecting member 121a, the second reflecting member 121b, and the third reflecting member 121c can be formed on the substrate 100. The barrier metal 140 can be formed to cover the peripheral portion of each reflecting member 121. Next, the insulating film 141 can be formed on the substrate 100 to cover the plurality of reflecting members 121 including the first reflecting member 121a, the second reflecting member 121b, and the third reflecting member 121c, and the substrate 100. Here, the insulating film 141 may be provided with the first portion PP1, the second portion PP2, and the third portion PP3 each of which functions as the optical adjustment film as described above. The first portion PP1, the second portion PP2, and the third portion PP3 can be formed by repeating a film formation step of forming an insulating layer and a patterning step of patterning the insulating layer for a plurality of times. This patterning step can include a photolithography step and an etching step.

Then, steps (a photolithography step and an etching step) for forming contact holes CH for electrically connecting the reflecting members 121 and the lower electrodes 131 can be executed. Note that in a case where the reflecting members 121 are not electrically connected to the lower electrodes 131, these steps are unnecessary.

Then, a step of forming the lower electrodes 131 above the reflecting members 121 via the insulating film 141 can be executed. In one viewpoint, in this step, the first lower electrode 131a and the second lower electrode 131b can be formed above the first reflecting member 121a and the second reflecting member 121b, respectively, via the insulating film 141. The spacing between the first reflecting member 121a and the first lower electrode 131a and the spacing between the second reflecting member 121b and the second lower electrode 131b are different from each other. In another viewpoint, in this step, the first lower electrode 131a, the second lower electrode 131b, and the third lower electrode 131c can be formed above the first reflecting member 121a, the second reflecting member 121b, and the third reflecting member 121c, respectively, via the insulating film 141. The spacing between the first reflecting member 121a and the first lower electrode 131a, the spacing between the second reflecting member 121b and the second lower electrode 131b, and the spacing between the third reflecting member 121c and the third lower electrode 131c are different from each other.

Then, the organic compound film 152 can be formed on the lower electrode 131. The organic compound film 152 can include, for example, a hole injection layer, a hole transport layer, an electron blocking layer, a light emitting layer, a hole blocking layer, an electron transport layer, an electron injection layer, and the like. Then, the upper electrode 153 can be formed.

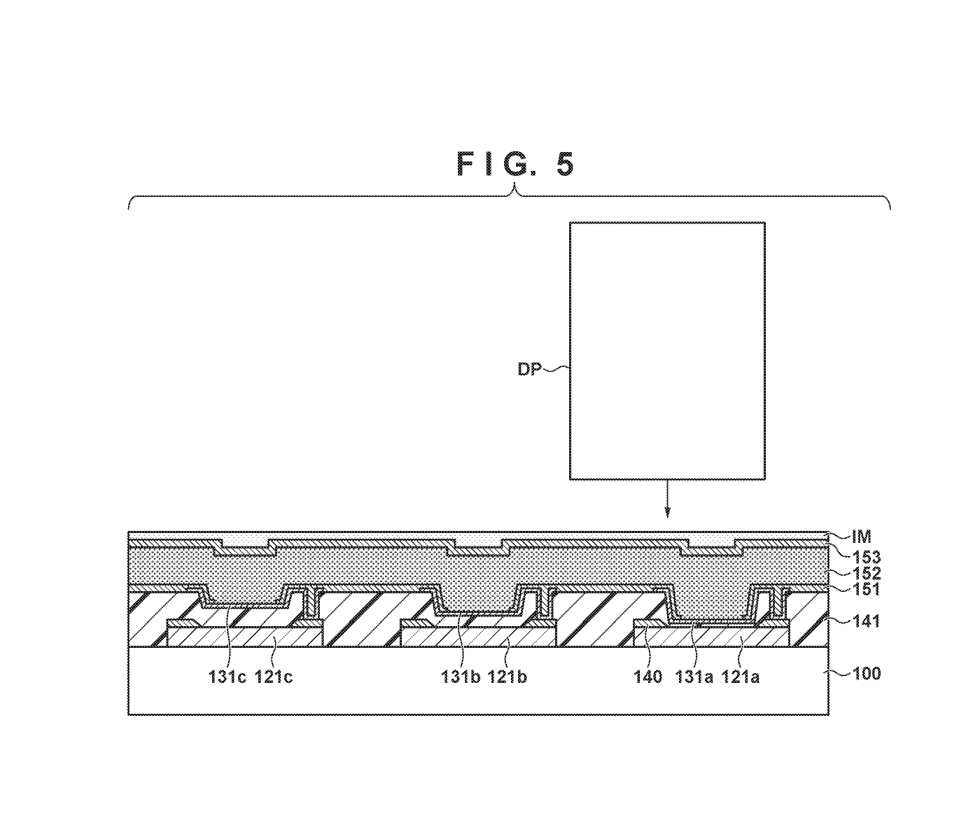

With reference to FIGS. 5 to 8, processing for forming the planarizing film 154 on the upper electrode 153 will be described below. First, as schematically shown in FIG. 5, in the planarization apparatus IAP, a step of arranging the curable composition IM by the dispenser DP to cover the upper electrode 153 is executed. This step is an example of a step of arranging the curable composition IM by the dispenser DP on a structure including at least the substrate 100, the plurality of lower electrodes 131, and the bank insulating film 151. Alternatively, this step is an example of a step of arranging the curable composition IM by the dispenser DP on a structure including the organic compound film 152 and the upper electrode 153 in addition to the substrate 100, the plurality of lower electrodes 131, and the bank insulating film 151.

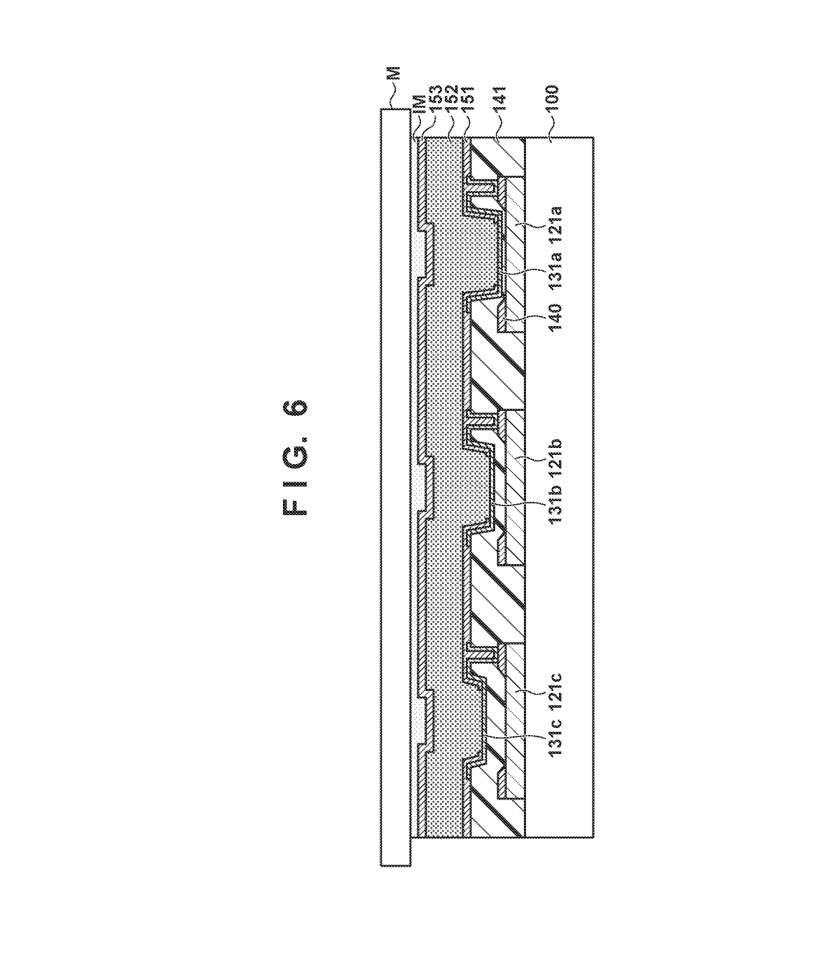

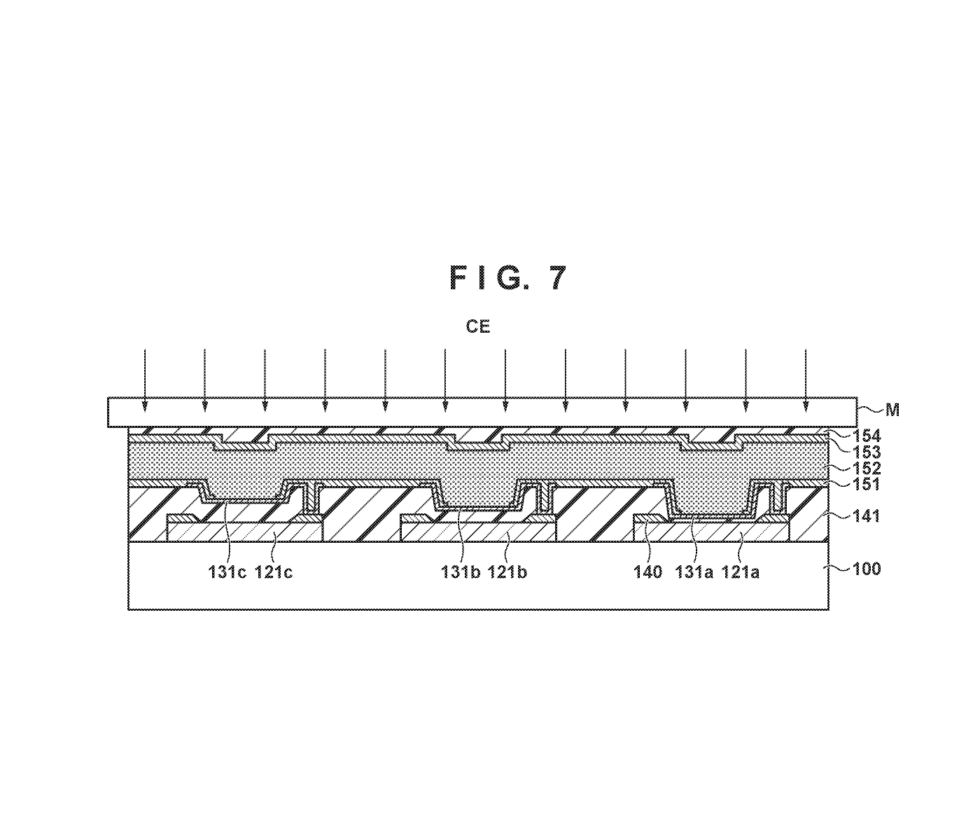

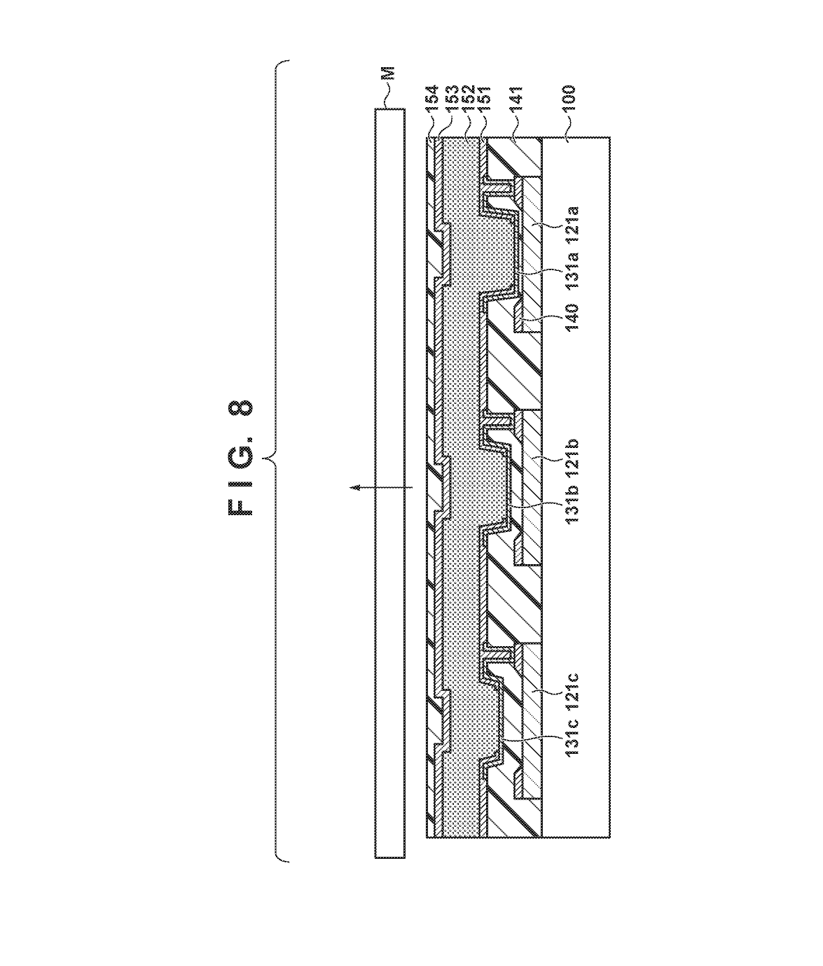

Then, as schematically shown in FIG. 6, in the planarization apparatus IAP, a step of bringing a superstrate serving as the mold M into contact with the curable composition IM arranged on the upper electrode 153 is executed. Then, as schematically shown in FIG. 7, a step of curing the curable composition IM by applying curing energy CE to the curable composition IM by the curing unit CU in a state in which the curable composition IM and the mold M are in contact with each other is executed. With this, the planarizing film 154 formed of a cured product of the curable composition IM is formed. Then, as schematically shown in FIG. 8, a step of separating the mold M from the planarizing film 154 is executed.

By repeating the steps for forming a planarizing film schematically shown in FIGS. 5 to 8 for a plurality of times, the planarizing film 154 having a stacked structure formed from a plurality of layers each formed of a cured product of the curable composition may be formed.

Hereinafter, sealing films (for example, the sealing films 155, 156, and 157) can be formed on the planarizing film 154, as needed. On the planarizing film 154 or the sealing films (for example, the sealing films 155, 156, and 157), a color filter array and/or a microlens array may be formed, as needed.

A manufacturing method of the light emitting device 1 schematically shown in FIG. 3 will be exemplarily described below. The manufacturing method of the light emitting device 1 schematically shown in FIG. 3 may be similar to the manufacturing method of the light emitting device 1 schematically shown in FIG. 1 in the manufacturing method of the substrate 100 and the method from formation of the plurality of lower electrodes 131 to formation of the organic compound film 152.

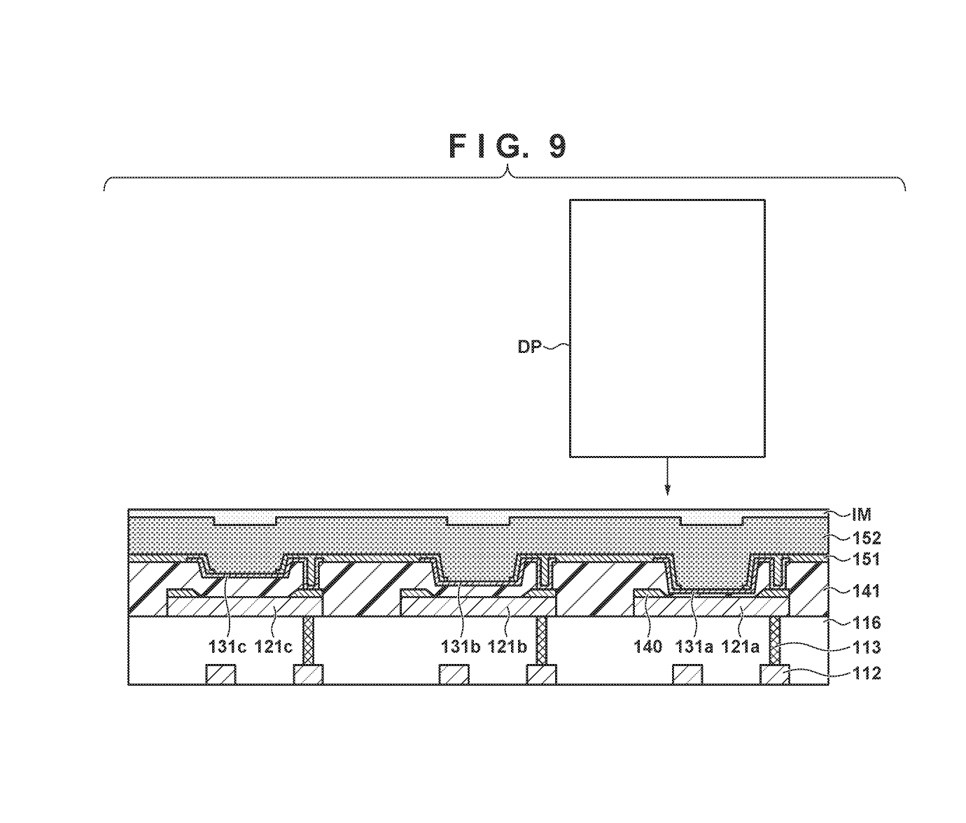

With reference to FIGS. 9 to 12, processing for forming the planarizing film 154 on the organic compound film 152 will be described below. First, as schematically shown in FIG. 9, in the planarization apparatus IAP, a step of arranging the curable composition IM by the dispenser DP to cover the organic compound film 152 is executed. This step is an example of a step of arranging the curable composition IM by the dispenser DP on a structure including at least the substrate 100, the plurality of lower electrodes 131, and the bank insulating film 151. Alternatively, this step is an example of a step of arranging the curable composition IM by the dispenser DP on a structure including the organic compound film 152 in addition to the substrate 100, the plurality of lower electrodes 131, and the bank insulating film 151.

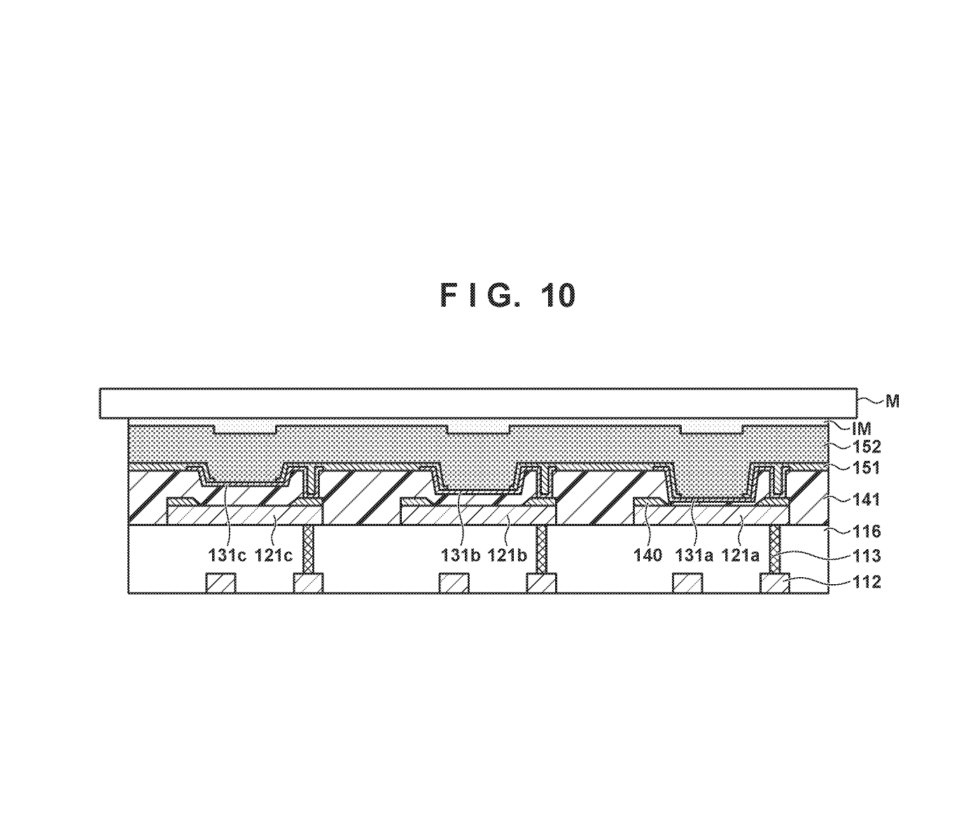

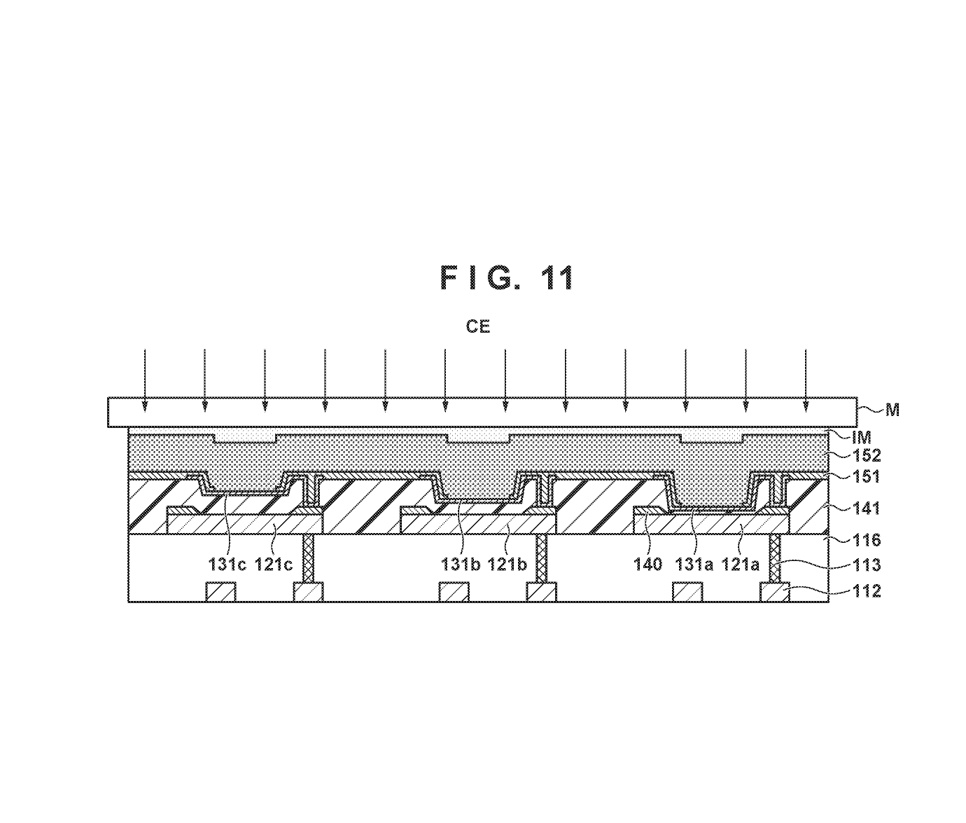

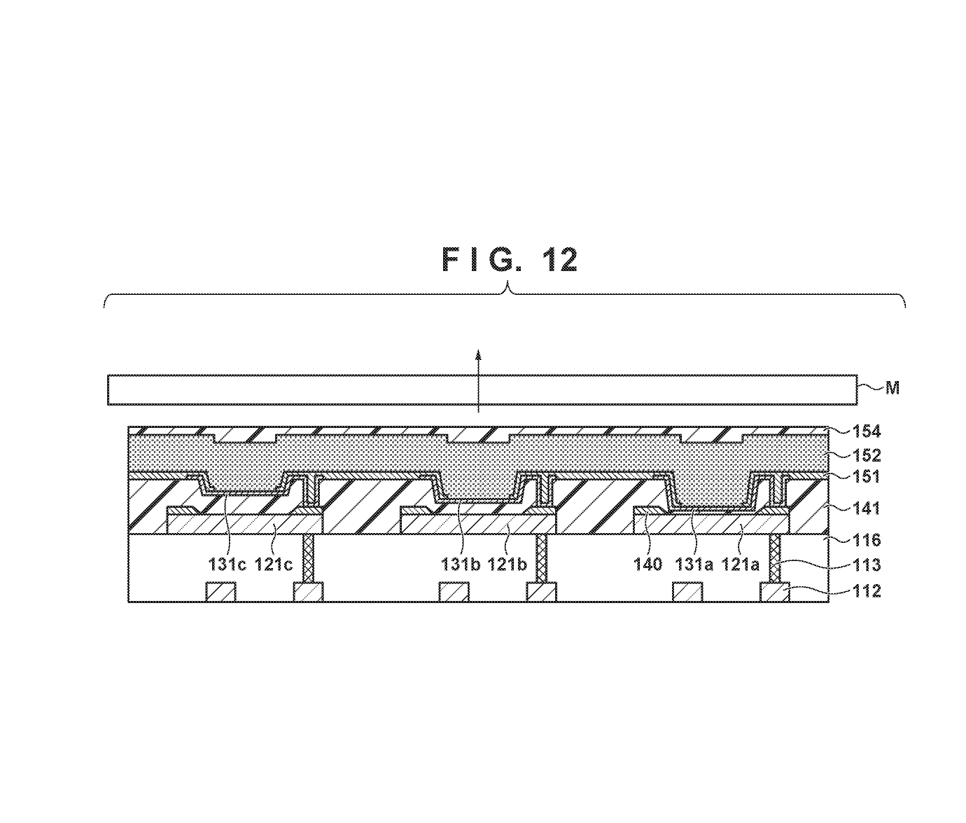

Then, as schematically shown in FIG. 10, in the planarization apparatus IAP, a step of bringing a superstrate serving as the mold M into contact with the curable composition IM arranged on the organic compound film 152 is executed. Then, as schematically shown in FIG. 11, a step of curing the curable composition IM by applying the curing energy CE to the curable composition IM by the curing unit CU in a state in which the curable composition IM and the mold M are in contact with each other is executed. With this, the planarizing film 154 formed of a cured product of the curable composition IM is formed. Then, as schematically shown in FIG. 12, a step of separating the mold M from the planarizing film 154 is executed.

By repeating the steps for forming a planarizing film schematically shown in FIGS. 9 to 12 for a plurality of times, the planarizing film 154 having a stacked structure formed from a plurality of layers each formed of a cured product of the curable composition may be formed.

Then, the upper electrode 153 can be formed on the planarizing film 154. Sealing films (for example, the sealing films 155, 156, and 157) can be formed on the upper electrode 153, as needed. On the upper electrode 153 or the sealing films (for example, the sealing films 155, 156, and 157), a color filter array and/or a microlens array may be formed, as needed.

As described above, the method of curing the curable composition IM after planarizing the surface of the curable composition IM by bringing the mold M into contact with the curable composition IM is advantageous in reducing the manufacturing cost and/or improving the optical characteristic. On the other hand, in a vapor deposition method such as a CVD method, the unevenness of an underlying layer easily appears in the surface of the planarizing film, and a long time is required to form a thick planarizing film. In a spin coating method, the unevenness depending on the characteristics of a material such as the viscosity, rotation control of the substrate, or the like can be formed in the surface of the planarizing film.

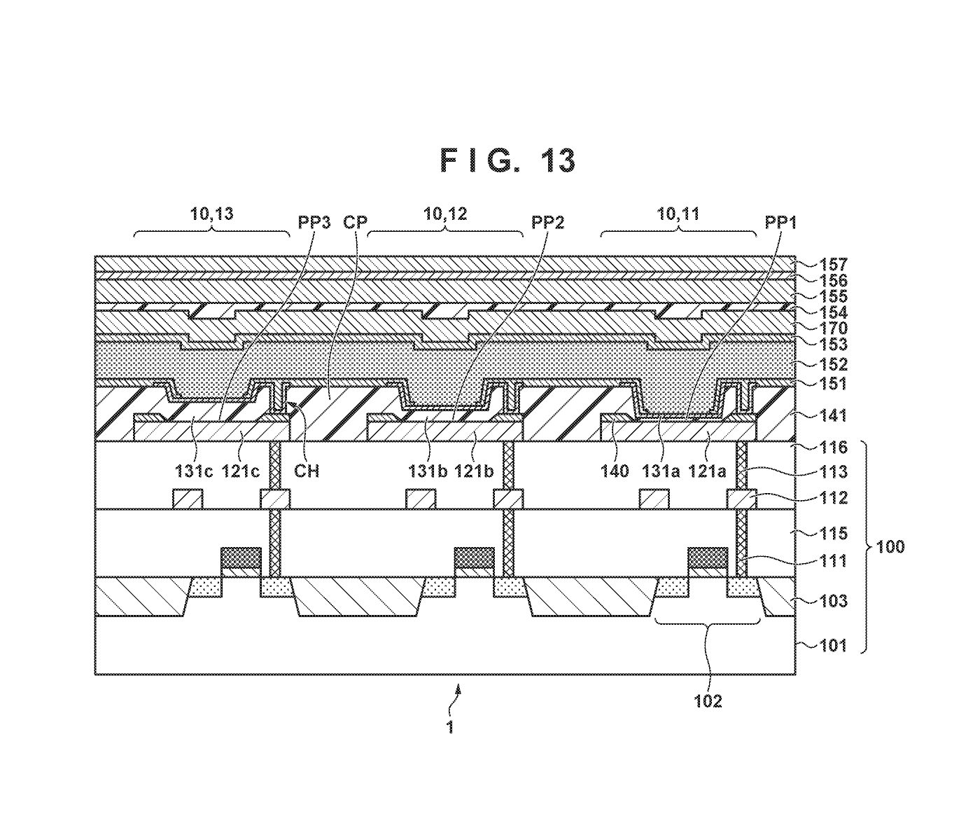

FIG. 13 shows the first modification of the light emitting device 1 shown in FIG. 1. In the first modification, the light emitting device 1 can include a sealing film 170 arranged between the upper electrode 153 and the planarizing film 154. The sealing film 170 can be an inorganic film, for example, a silicon nitride film. On the planarizing film 154, one or a plurality of sealing films can be arranged. In an example, the first sealing film 155, the second sealing film 156, and the third sealing film 157 can be arranged on the planarizing film 154. The first sealing film 155 is, for example, a silicon nitride film. The second sealing film 156 is, for example, an aluminum oxide film. The third sealing film 157 is, for example, a silicon nitride film. On these sealing films, a color filter array and/or a microlens array may be arranged.

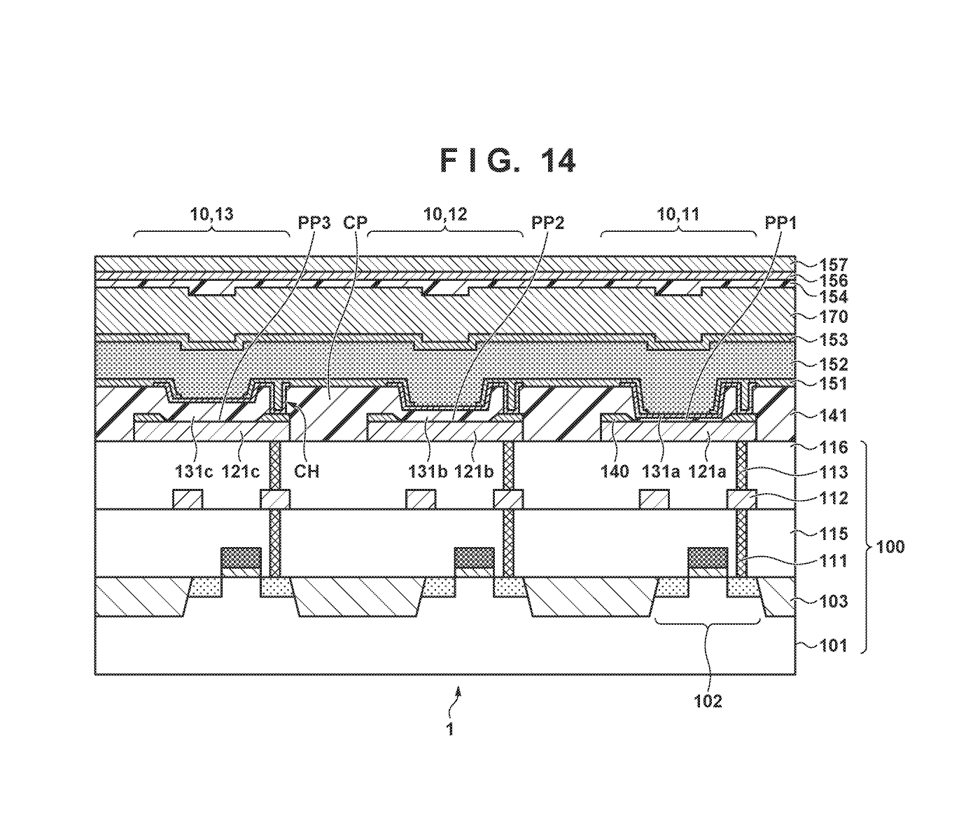

FIG. 14 shows the second modification of the light emitting device 1 shown in FIG. 1. In the second modification, the light emitting device 1 can include the sealing film 170 arranged between the upper electrode 153 and the planarizing film 154. The sealing film 170 can be an inorganic film, for example, a silicon nitride film. On the planarizing film 154, the second sealing film 156 and the third sealing film 157 can be arranged. The second sealing film 156 is, for example, an aluminum oxide film. The third sealing film 157 is, for example, a silicon nitride film. On these sealing films, a color filter array and/or a microlens array may be arranged.

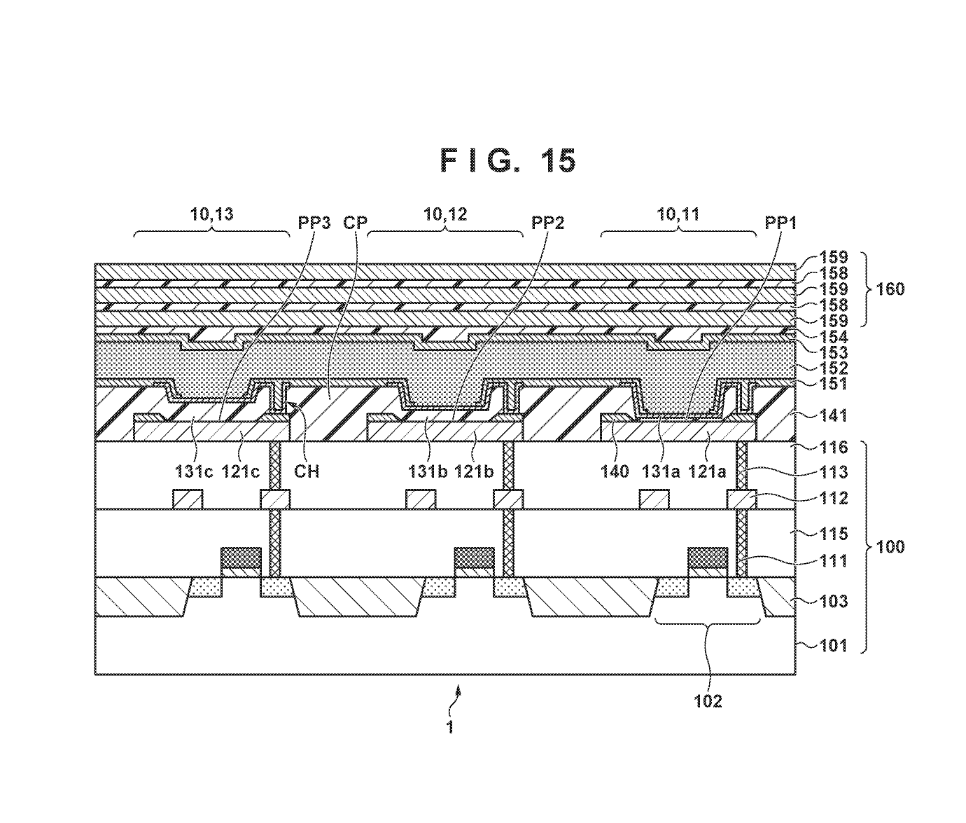

FIG. 15 shows the third modification of the light emitting device 1 shown in FIG. 1. In the third modification, the light emitting device 1 can include a stacked structure 160 arranged on the planarizing film 154. The stacked structure 160 can include a cured product film 158 formed of a cured product of the curable composition, and a silicon compound film 159. The stacked structure 160 may have a structure where a unit constituted by the cured product film 158 formed of a cured product of the curable composition and the silicon compound film 159 is repeatedly arranged. On the stacked structure 160, a color filter array and/or a microlens array may be arranged.

Each component will be exemplarily described in detail below.

### Configuration of Sub-pixel (Organic Light Emitting Element

The organic light emitting element as the sub-pixel 10 can be formed by using the lower electrode 131 as an anode and the upper electrode 153 as a cathode. A protection layer, a color filter, a microlens, and the like may be provided on a cathode. If a color filter is provided, a planarizing layer may be provided between the protection layer and the color filter. The planarizing layer can be formed using acrylic resin or the like. The same applies to a case where a planarizing layer is provided between the color filter and the microlens.

The semiconductor substrate 101 may be a non-semiconductor substrate such as quartz, glass, a silicon wafer, a resin, or a metal. In this case, a plurality of thin-film transistors can be formed on the non-semiconductor substrate. An insulating layer can be formed so as to cover the plurality of thin-film transistors, a wiring pattern can be arranged on the insulating layer, and an insulating layer can be further arranged on the wiring pattern. Contact holes can be formed in these insulating layers, and each contact hole can be filled with a plug. The insulating layer can be formed of, for example, a resin such as polyimide, silicon oxide, or silicon nitride.

### Electrode

Among the lower electrode and the upper electrode, the electrode having a high potential is the anode, and the other is the cathode. It can also be said that the electrode that supplies holes to the light emitting layer is the anode and the electrode that supplies electrons is the cathode.

As the constituent material of the anode, a material having a large work function may be selected. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used as the constituent material of the anode.

One of these electrode materials may be used singly, or two or more of them may be used in combination. The anode may be formed by a single layer or a plurality of layers.

As a reflective electrode, for example, chromium, aluminum, silver, titanium, copper, tungsten, molybdenum, an alloy thereof, a stacked layer thereof, or the like can be used. The above materials can function as a reflective film having no role as an electrode. If a transparent electrode is used as the electrode, an oxide transparent conductive layer made of indium tin oxide (ITO), indium zinc oxide, or the like can be used, but the invention is not limited thereto. A photolithography technique can be used to form the electrode.

On the other hand, as the constituent material of the cathode, a material having a small work function may be selected. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Silver may be used as the cathode. To suppress aggregation of silver, a silver alloy may be used. The ratio of the alloy is not limited as long as aggregation of silver can be suppressed. For example, the ratio between silver and another metal may be 1 : 1, 3 : 1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but if direct current sputtering or alternating current sputtering is used, the good coverage is achieved for the film to be formed, and the resistance of the cathode can be lowered.

In a case where the first electrode is the cathode and the second electrode is the anode, a high color gamut and low-voltage driving can be achieved by forming the electron transport material and charge transport layer and forming the light emitting layer on the charge transport layer.

### Organic Compound Layer

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer may be arranged between the first and second electrodes, and may be arranged in contact with the first and second electrodes.

### Protection Layer

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation layer made of silicon nitride or the like may be provided on the cathode to suppress permeation of water or the like into the organic compound layer. For example, the protection layer can be formed by forming the cathode, transferring it to another chamber without breaking the vacuum, and forming silicon nitride having a thickness of 2 μm by the CVD method. The protection layer may be provided using an atomic layer deposition (ALD) method after deposition of the protection layer using the CVD method. The material of the protection layer by the ALD method is not limited but can be silicon nitride, silicon oxide, aluminum oxide, or the like. Silicon nitride may further be formed by the CVD method on the protection layer formed by the ALD method. The protection layer formed by the ALD method may have a film thickness smaller than that of the protection layer formed by the CVD method. More specifically, the film thickness of the protection layer formed by the ALD method may be 50% or less, or 10% or less of that of the protection layer formed by the CVD method.

### Color Filter

A color filter may be provided on the protection layer. For example, a color filter considering the size of the organic light emitting element may be provided on another substrate, and the substrate with the color filter formed thereon may be bonded to the substrate with the organic light emitting element provided thereon. Alternatively, for example, a color filter may be patterned on the above-described protection layer using a photolithography technique. The color filter may be formed from a polymeric material.

### Planarizing Layer

A planarizing layer may be arranged between the color filter and the protection layer. The planarizing layer is provided to reduce unevenness of the layer below the planarizing layer. The planarizing layer may be called a material resin layer without limiting the purpose of the layer. The planarizing layer may be formed from an organic compound, and may be made of a low-molecular material or a polymeric material. In consideration of reduction of unevenness, a polymeric organic compound may be used for the planarizing layer.

The planarizing layers may be provided above and below the color filter. In that case, the same or different constituent materials may be used for these planarizing layers. More specifically, examples of the material of the planarizing layer include polyvinyl carbazole resin, polycarbonate resin, polyester resin, ABS resin, acrylic resin, polyimide resin, phenol resin, epoxy resin, silicone resin, and urea resin.

### Microlens

The organic light emitting device may include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface can be arranged on the functional layer (light emitting layer) side of the first surface. For this configuration, the microlens needs to be formed on the light emitting device. If the functional layer is an organic layer, a process which produces high temperature in the manufacturing step of the microlens may be avoided. In addition, if it is configured to arrange the second surface on the functional layer side of the first surface, all the glass transition temperatures of an organic compound forming the organic layer may be 100°C or more. For example, 130°C or more is suitable.

### Counter Substrate

A counter substrate may be arranged on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light emitting layer, hole blocking layer, electron transport layer, electron injection layer, and the like) forming the organic light emitting element according to an embodiment of the present disclosure may be formed by the method to be described below.

The organic compound layer forming the organic light emitting element according to the embodiment of the present disclosure can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### Pixel Circuit

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### Pixel

The organic light emitting device includes a plurality of pixels. Each pixel includes sub-pixels that emit light components of different colors. The sub-pixels may include, for example, R, G, and B emission colors, respectively.

In each pixel, a region also called a pixel opening emits light. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. A shape which is not a correct shape but is close to a rectangle is included in a rectangle, as a matter of course. The shape of the sub-pixel and the pixel arrangement can be used in combination.

### Application of Organic Light Emitting Element of Embodiment of Present Disclosure

The organic light emitting element according to an embodiment of the present disclosure can be used as a constituent member of a display device or an illumination device. In addition, the organic light emitting element is applicable to the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

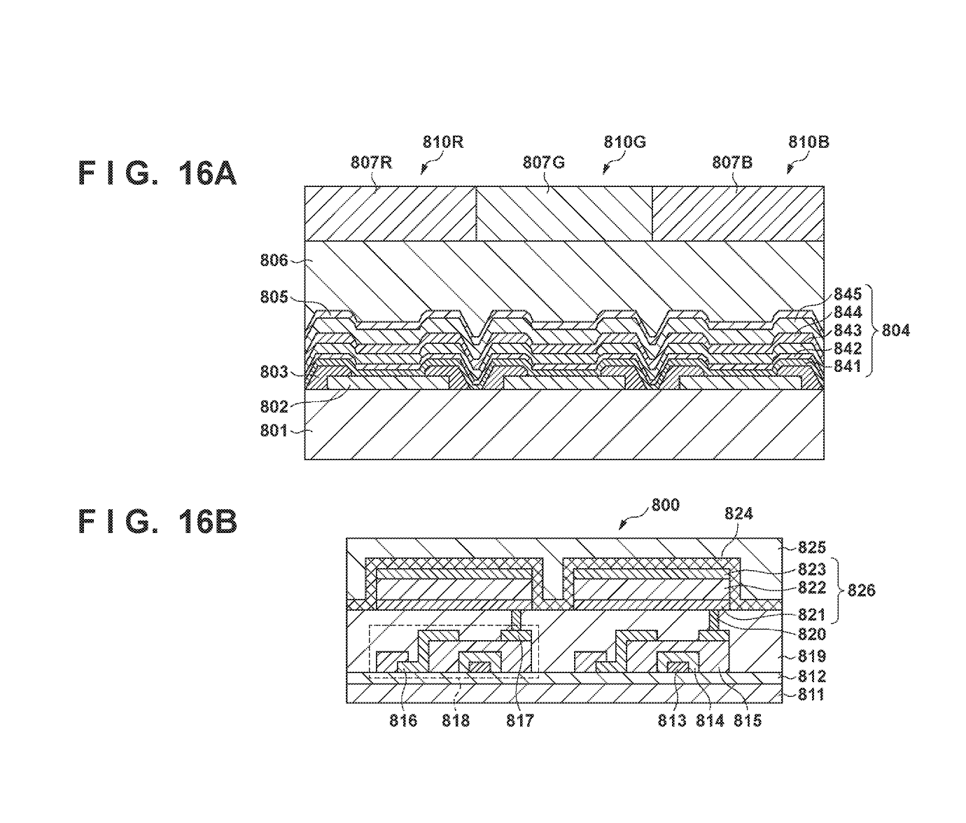

More details will be described next with reference to the accompanying drawings. FIG. 16A shows an example of the pixel. The pixel includes a plurality of sub-pixels 810 (pixels 150). The sub-pixels are divided into sub-pixels 810R, 810G, and 810B by emitted light components. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 can include a transistor and a capacitive element arranged in the interlayer insulating layer 801 or a layer below it. The transistor and the first electrode can electrically be connected via a contact hole (not shown) or the like.

The insulating layer 803 can also be called a bank or a pixel isolation film. The insulating layer 803 covers the end of the first electrode, and is arranged to surround the first electrode. A portion of the first electrode where no insulating layer 803 is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode may be a transparent electrode, a reflective electrode, or a semi-transmissive electrode.

The protection layer 806 suppresses permeation of water into the organic compound layer. The protection layer is shown as a single layer but may include a plurality of layers. Each layer can be an inorganic compound layer or an organic compound layer.

The color filter 807 is divided into color filters 807R, 807G, and 807B by colors. The color filters can be formed on a planarizing film (not shown). A resin protection layer (not shown) may be arranged on the color filters. The color filters can be formed on the protection layer 806. Alternatively, the color filters can be provided on the counter substrate such as a glass substrate, and then the substrate may be bonded.

FIG. 16B shows a part of the light emitting device 1 formed as a display device 800. FIG. 16B shows an organic light emitting element 826, and a TFT 818 as an example of a transistor. A substrate 811 of glass, silicon, or the like is provided and an insulating layer 812 is provided on the substrate 811. The active element such as the TFT 818 is arranged on the insulating layer, and a gate electrode 813, a gate insulating film 814, and a semiconductor layer 815 of the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film.

A method of electrically connecting the electrodes (anode and cathode) included in the organic light emitting element 826 and the electrodes (source electrode and drain electrode) included in the TFT is not limited to that shown in FIG. 16B. That is, one of the anode and cathode and one of the source electrode and drain electrode of the TFT are electrically connected. The TFT indicates a thin-film transistor.

In the display device 800 shown in FIG. 16B, an organic compound layer is illustrated as one layer. However, an organic compound layer 822 may include a plurality of layers. A first protection layer 824 and a second protection layer 825 are provided on a cathode 823 to suppress deterioration of the organic light emitting element.

A transistor is used as a switching element in the display device 800 shown in FIG. 16B, but may be used as another switching element instead.

The transistor used in the display device 800 shown in FIG. 16B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display device 800 shown in FIG. 16B may be formed in the substrate such as a silicon substrate. Forming the transistor in the substrate means forming the transistor by processing the substrate such as a silicon substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Here, the switching element according to this embodiment is not limited to the TFT, and may be a transistor formed from low-temperature polysilicon or an active matrix driver formed on the substrate such as a silicon substrate. The term "on the substrate" may mean "in the substrate". Whether to provide a transistor in the substrate or use a TFT is selected based on the size of the display unit. For example, if the size is about 0.5 inch, the organic light emitting element is preferably provided on the silicon substrate.

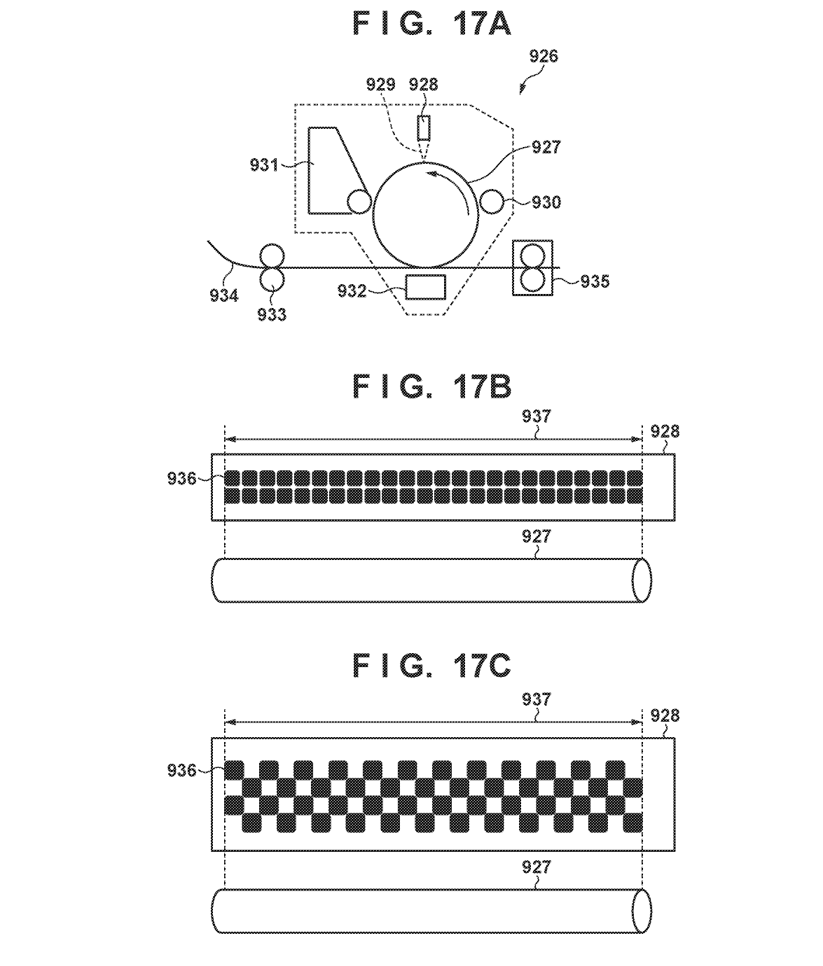

FIGS. 17A to 17C are schematic views showing an example of an image forming device using the light emitting device 1 according to this embodiment. An image forming device 926 shown in FIG. 17A includes a photosensitive member 927, an exposure light source 928, a developing unit 931, a charging unit 930, a transfer device 932, a conveyance unit 933 (a conveyance roller in the arrangement shown in FIG. 17A), and a fixing device 935.

Light 929 is emitted from the exposure light source 928, and an electrostatic latent image is formed on the surface of the photosensitive member 927. The light emitting device 1 can be applied to the exposure light source 928. The developing unit 931 can function as a developing device that includes a toner or the like as a developing agent and applies the developing agent to the exposed photosensitive member 927. The charging unit 930 charges the photosensitive member 927. The transfer device 932 transfers the developed image to a print medium 934. The conveyance unit 933 conveys the print medium 934. The print medium 934 can be, for example, paper, a film, or the like. The fixing device 935 fixes the image formed on the print medium.

Each of FIGS. 17B and 17C is a schematic view showing a form in which a plurality of light emitting units 936 are arranged in the exposure light source 928 along the longitudinal direction of a long substrate. The light emitting device 1 can be applied to each of the light emitting units 936. That is, a plurality of the pixels 150 arranged in a pixel array 110 are arranged along the longitudinal direction of the substrate. A direction 937 is a direction parallel to the axis of the photosensitive member 927. This column direction matches the direction of the axis upon rotating the photosensitive member 927. This direction 937 can also be referred to as the long-axis direction of the photosensitive member 927.

FIG. 17B shows a form in which the light emitting units 936 are arranged along the long-axis direction of the photosensitive member 927. FIG. 17C shows a form, which is a modification of the arrangement of the light emitting units 936 shown in FIG. 17B, in which the light emitting units 936 are arranged in the column direction alternately between the first column and the second column. The light emitting units 936 are arranged at different positions in the row direction between the first column and the second column. In the first column, the plurality of light emitting units 936 are arranged apart from each other. In the second column, the light emitting unit 936 is arranged at the position corresponding to the space between the light emitting units 936 in the first column. Furthermore, in the row direction, the plurality of light emitting units 936 are arranged apart from each other. The arrangement of the light emitting units 936 shown in FIG. 17C can be referred to as, for example, an arrangement in a grid pattern, an arrangement in a staggered pattern, or an arrangement in a checkered pattern.

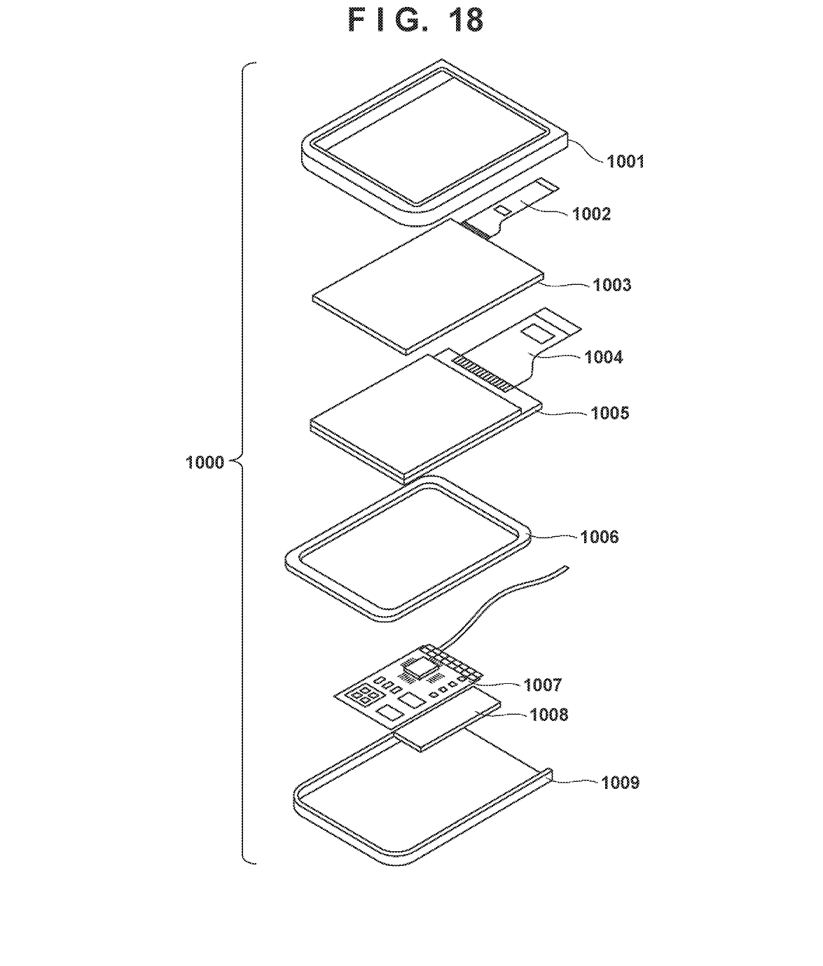

FIG. 18 is a schematic view showing an example of the display device using the light emitting device 1 according to this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display device 1000 is not a portable apparatus. Even when the display device 1000 is a portable apparatus, the battery 1008 need not be provided at this position. The light emitting device 1 can be applied to the display panel 1005. The pixels 150 arranged in the light emitting device 1 functioning as the display panel 1005 are connected to the active elements such as transistors arranged on the circuit board 1007 and operate.

The display device 1000 shown in FIG. 18 can be used for a display unit of a photoelectric conversion device (also referred to as an image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

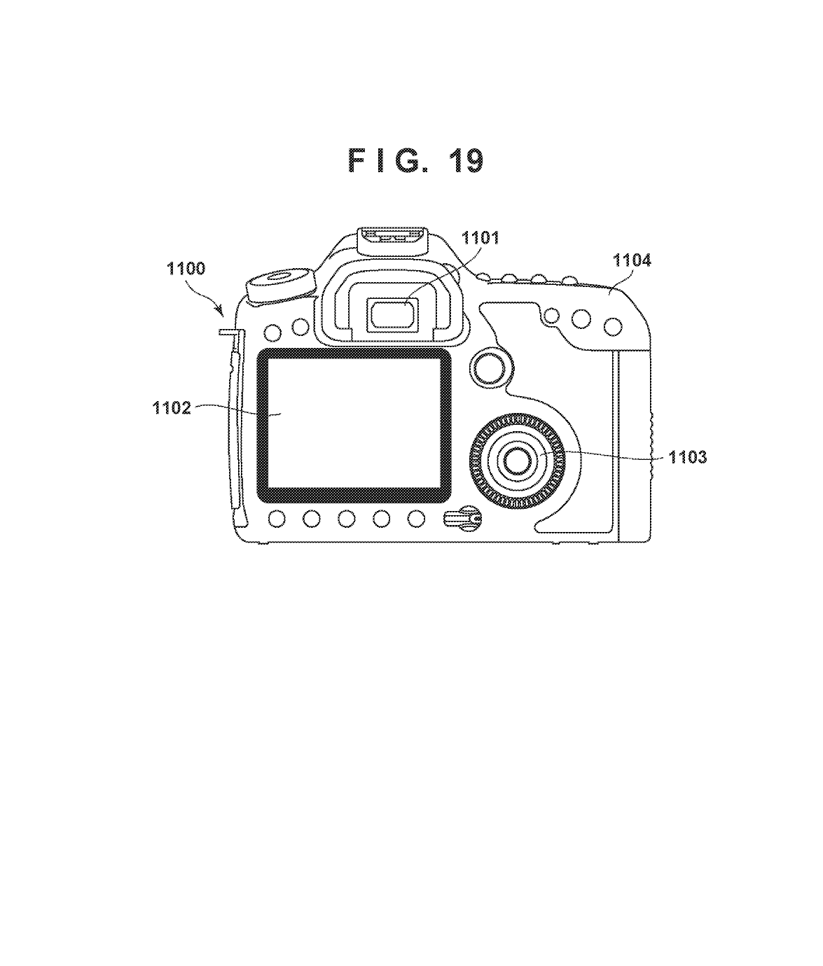

FIG. 19 is a schematic view showing an example of the photoelectric conversion device using the light emitting device 1 according to this embodiment. A photoelectric conversion device 1100 can include a viewfinder 1101, a rear display 1102, an operation unit 1103, and a housing 1104. The photoelectric conversion device 1100 can also be called an image capturing device. The light emitting device 1 according to this embodiment can be applied to the viewfinder 1101 or the rear display 1102 as a display unit. In this case, the pixel region of the light emitting device 1 can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time in many cases, so the information is preferably displayed as soon as possible. Therefore, the light emitting device 1 in which the pixel 150 including the light emitting element using the organic light emitting material such as an organic EL element is arranged in the pixel region may be used for the viewfinder 1101 or the rear display 1102. This is so because the organic light emitting material has a high response speed. The light emitting device 1 using the organic light emitting material can be used for the devices that require a high display speed more preferably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 1 may be applied to a display unit of an electronic apparatus. At this time, the display unit can have both a display function and an operation function. Examples of the portable terminal are a portable phone such as a smartphone, a tablet, and a head mounted display.

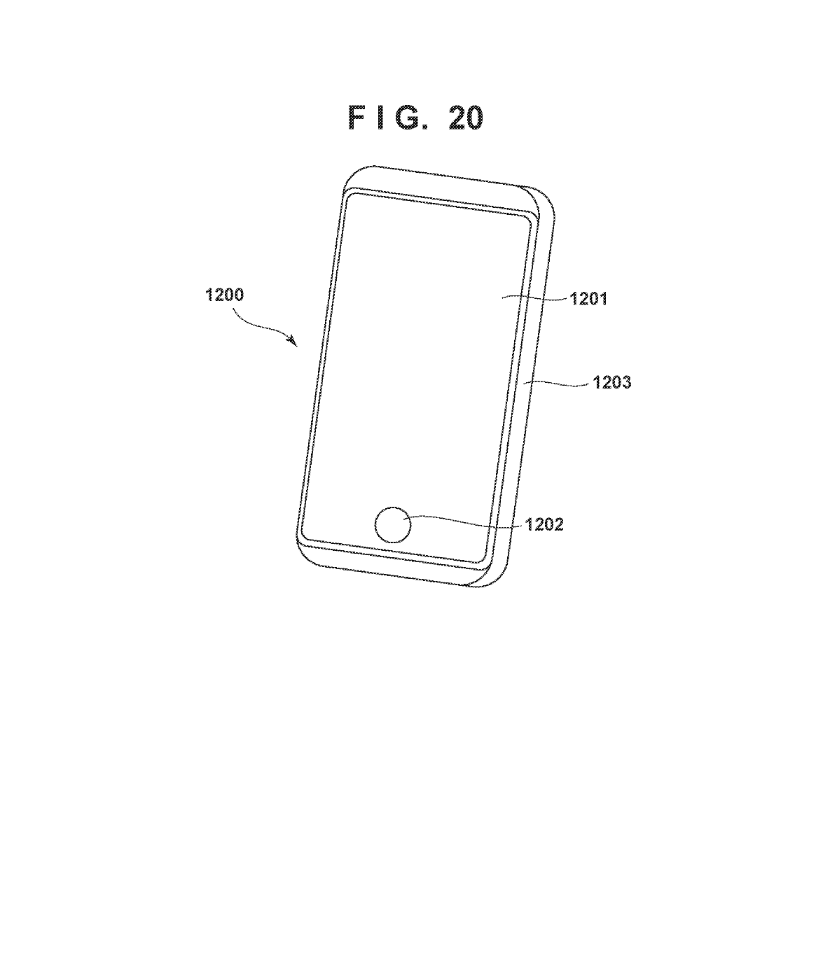

FIG. 20 is a schematic view showing an example of an electronic apparatus using the light emitting device 1 according to this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 1 according to this embodiment can be applied to the display unit 1201.

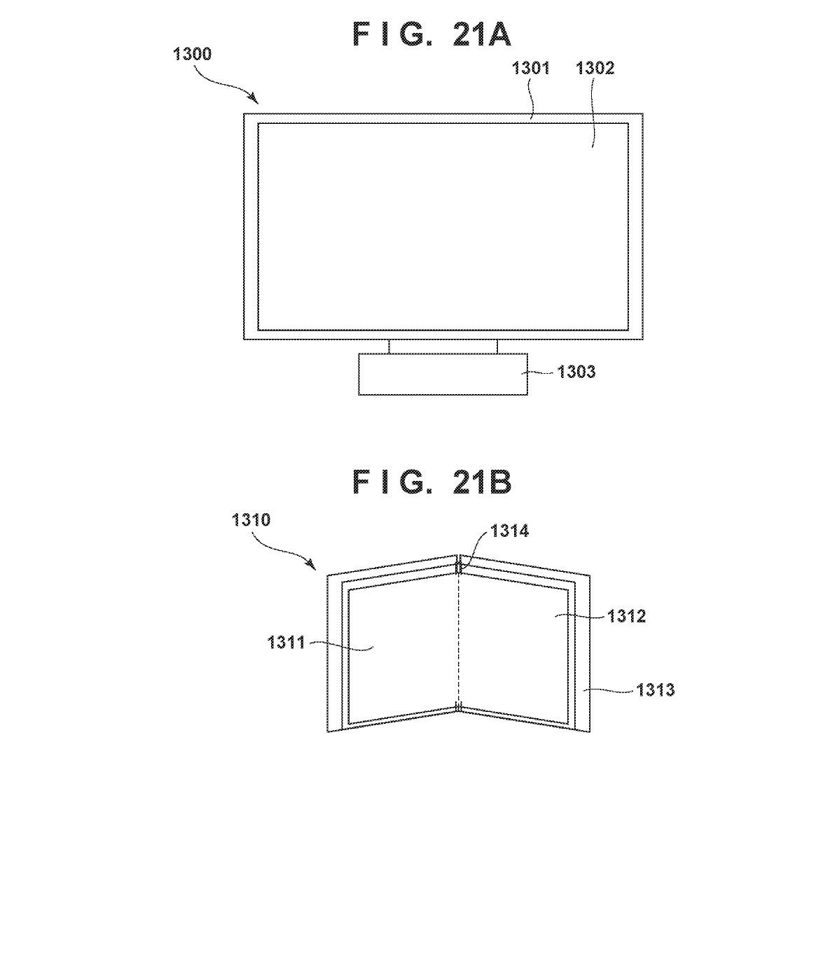

FIGS. 21A and 21B are schematic views showing examples of the display device using the light emitting device 1 according to this embodiment. FIG. 21A shows a display device such as a television monitor or a PC monitor. A display device 1300 includes a frame 1301 and a display unit 1302. The light emitting device 1 according to this embodiment can be applied to the display unit 1302. The display device 1300 can include a base 1303 that supports the frame 1301 and the display unit 1302. The base 1303 is not limited to the form shown in FIG. 21A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 21B is a schematic view showing another example of the display device using the light emitting device 1 according to this embodiment. A display device 1310 shown in FIG. 21B can be folded, and is a so-called foldable display device. The display device 1310 includes a first display unit 1311, a second display unit 1312, a housing 1313, and a bending point 1314. The light emitting device 1 according to this embodiment can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

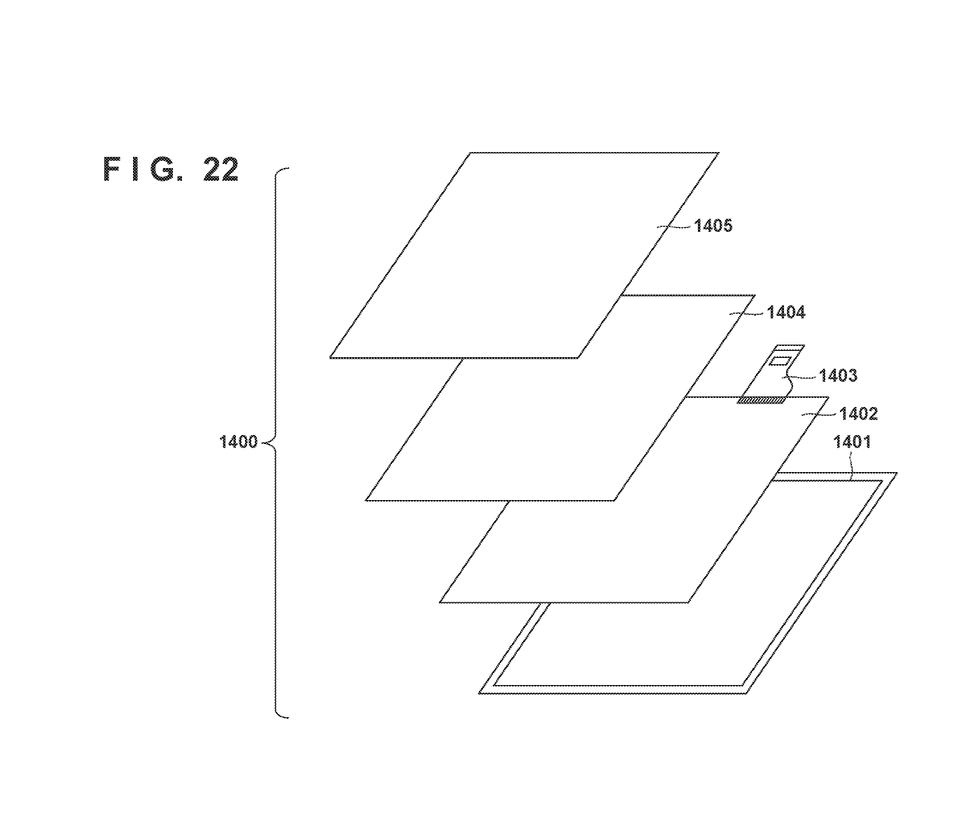

FIG. 22 is a schematic view showing an example of the illumination device using the light emitting device 1 according to this embodiment. An illumination device 1400 can include a housing 1401, a light source 1402, a circuit board 1403, an optical film 1404, and a light diffusing unit 1405. The light emitting device 1 according to this embodiment can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination device can also include a cover on the outermost portion, as needed. The illumination device 1400 can include both or one of the optical film 1404 and the light diffusing unit 1405.

The illumination device 1400 is, for example, a device for illuminating the interior of the room. The illumination device 1400 can emit white light, natural white light, or light of any color from blue to red. The illumination device 1400 can also include a light control circuit for controlling these light components. The illumination device 1400 can also include a power supply circuit connected to the light emitting device 1 functioning as the light source 1402. The power supply circuit is a circuit for converting an AC voltage into a DC voltage. White has a color temperature of 4,200 K, and natural white has a color temperature of 5,000 K. The illumination device 1400 may also include a color filter. In addition, the illumination device 1400 can include a heat radiation unit. The heat radiation unit radiates the internal heat of the device to the outside of the device, and examples are a metal having a high specific heat and liquid silicon.

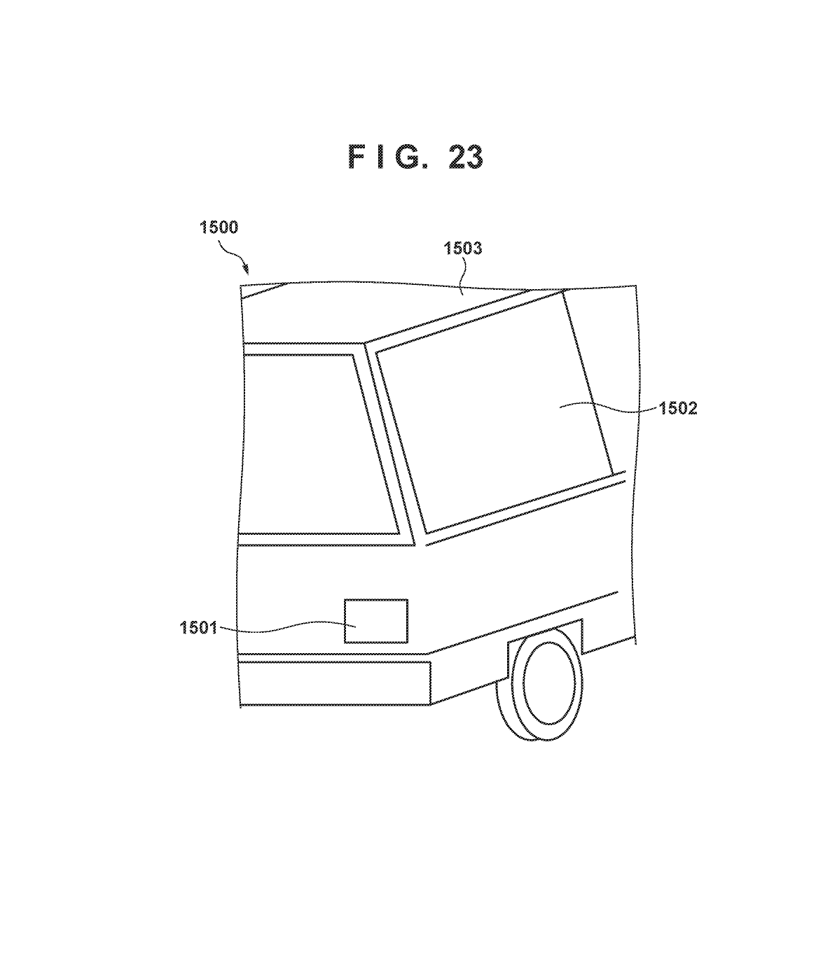

FIG. 23 is a schematic view of an automobile having a taillight as an example of a vehicle lighting appliance using the light emitting device 1 according to this embodiment. An automobile 1500 has a taillight 1501, and can have a form in which the taillight 1501 is turned on when performing a braking operation or the like. The light emitting device 1 according to this embodiment can be used as a headlight serving as a vehicle lighting appliance. The automobile is an example of a moving body, and the moving body may be a ship, a drone, an aircraft, a railroad car, an industrial robot, or the like. The moving body may include a main body and a lighting appliance provided in the main body. The lighting appliance may be used to make a notification of the current position of the main body.

The light emitting device 1 according to this embodiment can be applied to the taillight 1501. The taillight 1501 can include a protection member for protecting the light emitting device 1 functioning as the taillight 1501. The material of the protection member is not limited as long as the material is a transparent material with a strength that is high to some extent, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display such as a head-up display. For this transparent display, the light emitting device 1 according to this embodiment may be used. In this case, the constituent materials of the electrodes and the like of the light emitting device 1 are formed by transparent members.

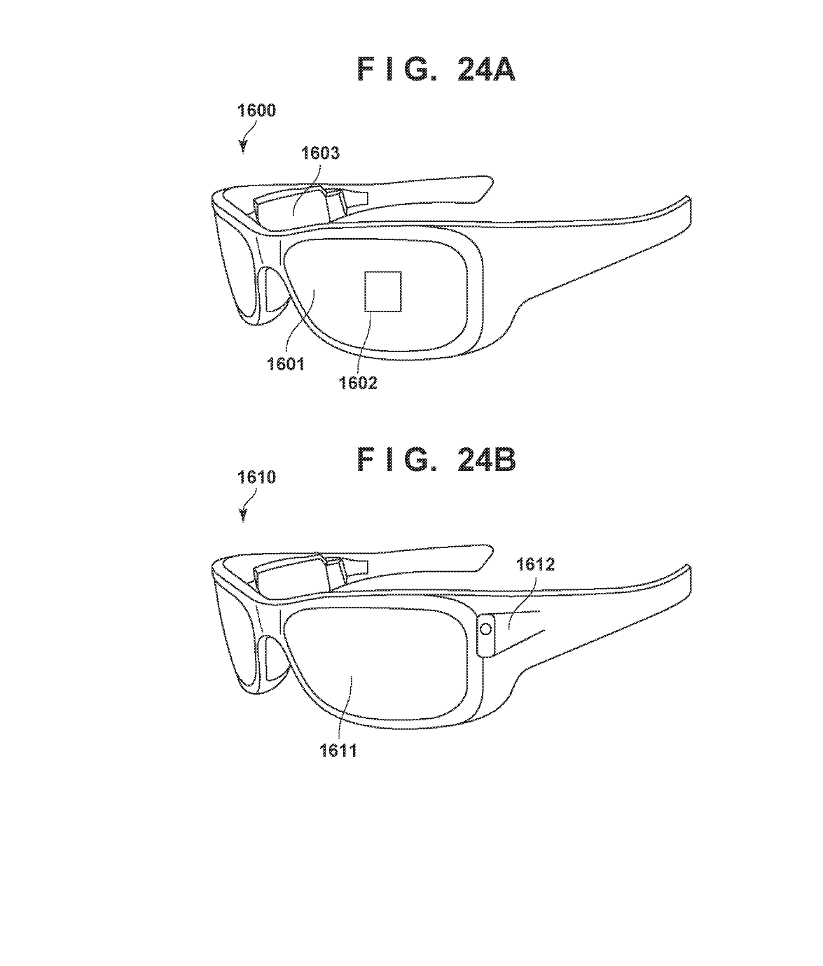

Further application examples of the light emitting device 1 according to this embodiment will be described with reference to FIGS. 24A and 24B. The light emitting device 1 can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 24A. An image capturing device 1602 such as a CMOS sensor or an SPAD is provided on the surface side of a lens 1601 of the glasses 1600. In addition, the light emitting device 1 according to this embodiment is provided on the back surface side of the lens 1601.

The glasses 1600 further include a control device 1603. The control device 1603 functions as a power supply that supplies electric power to the image capturing device 1602 and the light emitting device 1 according to each embodiment. In addition, the control device 1603 controls the operations of the image capturing device 1602 and the light emitting device 1. An optical system configured to condense light to the image capturing device 1602 is formed on the lens 1601.

Glasses 1610 (smartglasses) according to one application example will be described with reference to FIG. 24B. The glasses 1610 include a control device 1612, and an image capturing device corresponding to the image capturing device 1602 and the light emitting device 1 are mounted on the control device 1612. The image capturing device in the control device 1612 and an optical system configured to project light emitted from the light emitting device 1 are formed in a lens 1611, and an image is projected to the lens 1611. The control device 1612 functions as a power supply that supplies electric power to the image capturing device and the light emitting device 1, and controls the operations of the image capturing device and the light emitting device 1. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 1 according to the embodiment of the present disclosure can include an image capturing device including a light receiving element, and control a displayed image based on the line-of-sight information of the user from the image capturing device.

More specifically, the light emitting device 1 decides a first visual field region at which the user is gazing and a second visual field region other than the first visual field region based on the line-of-sight information. The first visual field region and the second visual field region may be decided by the control device of the light emitting device 1, or those decided by an external control device may be received. In the display region of the light emitting device 1, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 1, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 1, the image capturing device, or an external device. If the external device holds the AI program, it is transmitted to the light emitting device 1 via communication.

When performing display control based on line-of-sight detection, smartglasses further including an image capturing device configured to capture the outside can be applied. The smartglasses can display captured outside information in real time.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-175263, filed October 4, 2024, which is hereby incorporated by reference herein in its entirety.

What is claimed is:

1. A light emitting device comprising:
a plurality of lower electrodes arranged on a substrate;
a bank insulating film configured to cover a peripheral portion of an upper surface of each lower electrode of the plurality of lower electrodes and expose a central portion of the upper surface; and
a planarizing film arranged on at least the plurality of lower electrodes and the bank insulating film and formed of a cured product of a curable composition.

2. The light emitting device according to claim 1, further comprising:
an organic compound film arranged to cover the plurality of lower electrodes and the bank insulating film, and including a light emitting layer; and
an upper electrode arranged on the organic compound film,
wherein the planarizing film is arranged on the upper electrode.

3. The light emitting device according to claim 2, further comprising
one or a plurality of sealing films arranged on the planarizing film.

4. The light emitting device according to claim 2, further comprising
a plurality of sealing films arranged on the planarizing film,
wherein the plurality of sealing films include a first silicon nitride film, an aluminum oxide film arranged on the first silicon nitride film, and a second silicon nitride film arranged on the aluminum oxide film.

5. The light emitting device according to claim 2, further comprising:
a sealing film arranged between the upper electrode and the planarizing film; and
one or a plurality of sealing films arranged on the planarizing film.

6. The light emitting device according to claim 2, further comprising
a stacked structure arranged on the planarizing film,
wherein the stacked structure includes a cured product film formed of a cured product of a curable composition, and a silicon compound film.

7. The light emitting device according to claim 1, wherein
the bank insulating film is formed of an inorganic substance.

8. The light emitting device according to claim 1, wherein
a surface of the bank insulating film includes an inclined surface inclined toward the central portion, and
in a section perpendicular to an upper surface of the substrate, an angle formed by the inclined surface and the upper surface of the substrate is not less than 50°.

9. The light emitting device according to claim 8, wherein
the angle is not less than 80°.

10. The light emitting device according to claim 1, wherein
the planarizing film has a maximum film thickness of not less than 0.1 μm to not more than 2 μm.

11. The light emitting device according to claim 1, wherein
the planarizing film has a stacked structure formed from a plurality of layers, and each layer is formed of a cured product of a curable composition.

12. The light emitting device according to claim 11, wherein
the planarizing film is formed of a material selected from the group consisting of polyacetylene, poly(p-phenylene vinylene), polypyrrole, polythiophene, polyaniline, and polyphenylene sulfide.

13. The light emitting device according to claim 1, further comprising:
an organic compound film arranged to cover the plurality of lower electrodes and the bank insulating film, and including a light emitting layer; and
an upper electrode arranged on the organic compound film,
wherein the planarizing film is arranged between the organic compound film and the upper electrode.

14. A display device comprising:
the light emitting device according to claim 1; and
an active element connected to the light emitting device.

15. A photoelectric conversion device comprising:
an optical unit including a plurality of lenses;
an image sensor configured to receive light having passed through the optical unit; and
a display unit configured to display an image,
wherein the display unit displays an image captured by the image sensor, and includes the light emitting device according to claim 1.

16. An electronic apparatus comprising:
a housing provided with a display unit; and
a communication unit provided in the housing and configured to perform external communication,
wherein the display unit includes the light emitting device according claim 1.

17. A wearable device comprising:
a display device configured to display an image,
wherein the display device includes the light emitting device according to claim 1.

18. A manufacturing method of a light emitting device that comprises a plurality of lower electrodes arranged on a substrate, and a bank insulating film configured to cover a peripheral portion of an upper surface of each of the plurality of lower electrodes and expose a central portion of the upper surface, the method comprising:
arranging a curable composition on a structure including at least the substrate, the plurality of lower electrodes, and the bank insulating film;
bringing a superstrate into contact with the curable composition;
forming a planarizing film formed of a cured product of the curable composition by curing the curable composition in a state in which the curable composition and the superstrate are in contact with each other; and
separating the superstrate from the planarizing film.

19. The method according to claim 18, further comprising:
forming an organic compound film including a light emitting layer so as to cover the plurality of lower electrodes and the bank insulating film; and
forming an upper electrode on the organic compound film,
wherein in the arranging, the curable composition is arranged on the structure including the organic compound film and the upper electrode in addition to the substrate, the plurality of lower electrodes, and the bank insulating film.

20. The method according to claim 18, further comprising:
forming an organic compound film including a light emitting layer so as to cover the plurality of lower electrodes and the bank insulating film; and
forming an upper electrode on the organic compound film,
wherein in the arranging, the curable composition is arranged on the structure including the organic compound film in addition to the substrate, the plurality of lower electrodes, and the bank insulating film, and
the forming the upper electrode is executed after the forming the planarizing film.
